(19) United States
(12) Patent Application Publication
(10) Pub. No.: US 2026/0013134 A1
(43) Pub. Date: Jan. 8, 2026

(54) SEMICONDUCTOR DEVICES

(71) Applicant: Samsung Electronics Co., Ltd., Suwon-si (KR)

(72) Inventors: Pyeongwoo Kim, Suwon-si (KR); Jinhyuk Kim, Suwon-si (KR); Gilsung Lee, Suwon-si (KR); Jongmin Lee, Suwon-si (KR); Yitaek Choi, Suwon-si (KR)

(21) Appl. No.: 19/234,501

(22) Filed: Jun. 11, 2025

(30) Foreign Application Priority Data
Jul. 4, 2024 (KR) 10-2024-0088098

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

A semiconductor device includes a gate electrode, a memory channel structure and a first contact plug. The gate electrode structure is disposed on a substrate, and includes gate electrodes stacked and spaced apart from each other in a first direction substantially perpendicular to an upper surface of the substrate. Each of the gate electrodes extends in a second direction substantially parallel to the upper surface of the substrate. The memory channel structure extends through the gate electrode structure. The first contact plug extends into the gate electrode structure to contact an upper surface of a first gate electrode among the gate electrodes. The first contact plug extends through but is electrically insulated from a second gate electrode that is adjacent to the first gate electrode. The first contact plug has a shape of a portion of a circular ring.

### CROSS-REFERENCE TO RELATED APPLICATION

This application claims priority under 35 U.S.C. § 119 to Korean Patent Application No. 10-2024-0088098 filed on Jul. 4, 2024 in the Korean Intellectual Property Office, the disclosure of which is hereby incorporated by reference for all purposes in its entirety.

### FIELD

The inventive concepts relate to a semiconductor device. More particularly, the inventive concepts relate to a vertical memory device.

### BACKGROUND

In an electronic system requiring data storage, a high capacity semiconductor device that may store large amounts of data is desirable. Thus, a method of increasing the data storage capacity of the semiconductor device has been studied. For example, a semiconductor device including memory cells that may be 3-dimensionally stacked has been suggested.

Research on a method of efficiently forming contact plugs for transferring electrical signals to memory cells in the semiconductor device is required.

### SUMMARY

Example embodiments provide a semiconductor device having improved electrical characteristics.

According to some embodiments of the present disclousre, there is provided a semiconductor device. The semiconductor device may include a gate electrode, a memory channel structure and a first contact plug. The gate electrode structure may be disposed on a substrate, and may include gate electrodes stacked and spaced apart from each other in a first direction substantially perpendicular to an upper surface of the substrate. Each of the gate electrodes may extend in a second direction substantially parallel to the upper surface of the substrate. The memory channel structure may extend through the gate electrode structure. The first contact plug may extend partially through the gate electrode structure to contact an upper surface of a first gate electrode among the gate electrodes, wherein the upper surface of the first gate electrode faces away from the upper surface of the substrate. The first contact plug may extend through but be electrically insulated from a second gate electrode that is adjacent to the first gate electrode. The first contact plug may have a shape of a portion of a circular ring.

According to some embodiments of the present disclosure, there is provided a semiconductor device. The semiconductor device may include a gate electrode structure, a memory channel structure, a pair of contact plugs, and a plurality of first support structures. The gate electrode structure may on a substrate, and may include gate electrodes stacked and spaced apart from each other in a first direction substantially perpendicular to an upper surface of the substrate facing the gate electrode structure. Each of the gate electrodes may extend in a second direction substantially parallel to the upper surface of the substrate. The memory channel structure may extend through the gate electrode structure. The pair of contact plugs may extend into the gate electrode structure to contact an upper surface of a first gate electrode among the gate electrodes. Each of the pair of contact plugs may extend through but be electrically insulated from a second gate electrode that is adjacent to the first gate electrode. The pair of contact plugs may be spaced apart from each other in a third direction substantially parallel to the upper surface of the substrate and crossing the second direction, and the pair of contact plugs may be symmetrical in a straight line extending in the second direction. The plurality of first support structures may extend through the gate electrode structure and surround the pair of contact plugs in a plane substantially parallel to the upper surface of the substrate.

According to some embodiments of the present disclosure, there is provided a semiconductor device. The semiconductor device may include a substrate, a gate electrode structure, memory channel structures, a division pattern, first contact plugs, first support structures, a second support structure, third support structures and a second contact plug. The substrate may include first, second and third regions. The gate electrode structure may be adjacent to the first to third regions of the substrate, and may include gate electrodes stacked and spaced apart from each other in a first direction substantially perpendicular to an upper surface of the substrate facing the gate electrode structure. The gate electrodes may extend in a second direction substantially parallel to the upper surface of the substrate. Each of the memory channel structures may extend through the gate electrode structure on the first region of the substrate, and the memory channel structures may be spaced apart from each other in a horizontal direction substantially parallel to the upper surface of the substrate. The division pattern may extend in the second direction on the first and second regions of the substrate, and may extend through a first gate electrode and a second gate electrode over the first gate electrode among the gate electrodes included in the gate electrode structure. The first contact plugs may contact an upper surface of the first gate electrode, and may extend through but be electrically insulated from the second gate electrode on the second region of the substrate. The first contact plugs may be disposed at opposite sides of the division pattern. The first support structures may extend through the gate electrode structure on the second region of the substrate and surround the first contact plugs in a plane substantially parallel to the upper surface of the substrate. The second support structure may extend through the gate electrode structure on the second region of the substrate, and may be surrounded by the first contact plugs in the plane substantially parallel to the upper surface of the substrate. The third support structures may extend through the gate electrode structure on the third region of the substrate. The second contact plug may contact an upper surface of a third gate electrode among the gate electrodes included in the gate electrode structure, wherein upper surfaces of gate electrodes face away from the upper surface of the substrate. The second contact plug may extend through but be electrically insulated from a fourth gate electrode adjacent to the third gate electrode among the gate electrodes included in the gate electrode structure.

In the semiconductor device in accordance with some embodiments, the contact plugs contacting the gate electrodes and the support structures may be efficiently disposed so that the integration degree of the semiconductor device and the structural stability of the semiconductor device may be enhanced.

### BRIEF DESCRIPTION OF THE DRAWINGS

FIGS. 1 to 10 are plan views and cross-sectional views illustrating a method of forming a hole in accordance with example embodiments.

FIGS. 11 to 18 are plan views and cross-sectional views illustrating a method of forming a hole in accordance with example embodiments.

FIGS. 19 to 25 are plan views and cross-sectional views illustrating a semiconductor device in accordance with example embodiments.

FIGS. 26 to 65 are plan views and cross-sectional views illustrating a method of manufacturing a semiconductor device.

FIGS. 66 to 68 are plan views illustrating layouts of the fifth upper contact plugs, the first support structures and the second division pattern of semiconductor devices in accordance with example embodiments.

FIG. 69 is a plan view illustrating layouts of the first to third upper contact plugs and the second support structures of a semiconductor device in accordance with example embodiments.

FIG. 70 is a cross-sectional view illustrating a semiconductor device in accordance with example embodiments.

### DETAILED DESCRIPTION

The above and other aspects and features of the semiconductor devices and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, a vertical direction substantially perpendicular to an upper surface of a substrate may be referred to as a first direction D1, and two directions crossing each other among horizontal directions substantially parallel to the upper surface of the substrate may be referred to as second and third directions D2 and D3, respectively. In example embodiments, the second and third directions D2 and D3 may be substantially perpendicular to each other. A direction having an acute angle with respect to the second and third directions D2 and D3 among the horizontal directions may be referred to as a fourth direction D4. In example embodiments, the fourth direction D4 may have an angle of about 30° with respect to the third direction D3.

Each of the first to third directions D1, D2 and D3 may include both a direction indicated by an arrow and a direction inverse thereto, in the drawings. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. Likewise, the term “above” can encompass both an orientation of above and below. The device may be otherwise oriented (rotated 90 degrees or at other orientations), and the spatially relative descriptors used herein may be interpreted accordingly.

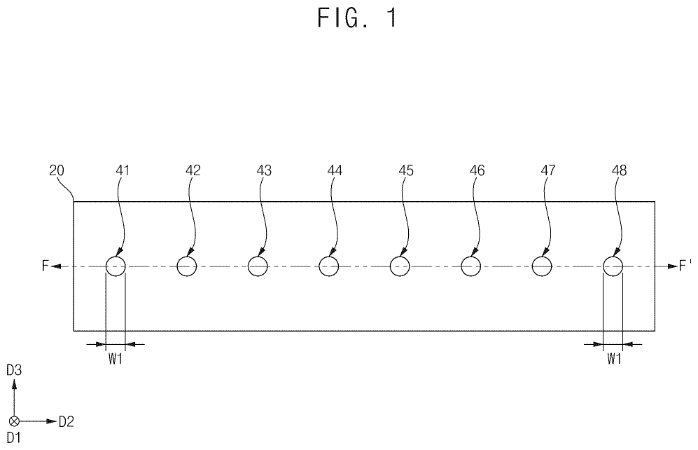

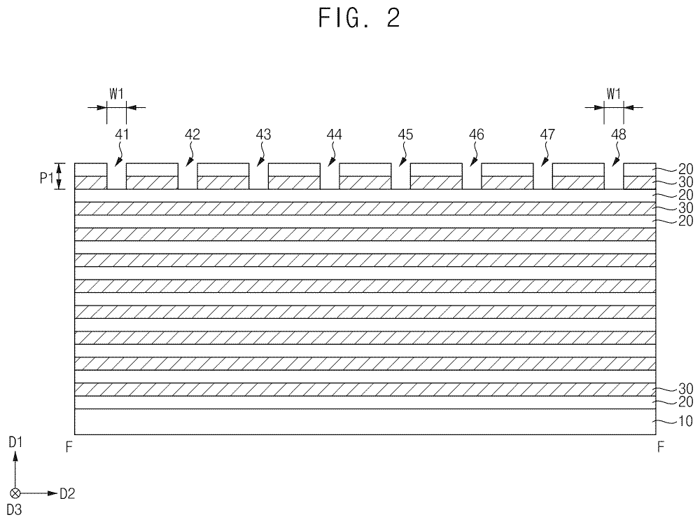

FIGS. 1 to 10 are plan views and cross-sectional views illustrating a method of forming a hole in accordance with example embodiments. Specifically, FIGS. 1, 3, 5, 7 and 9 are the plan views, and FIGS. 2, 4, 6, 8 and 10 are cross-sectional views taken along lines F-F′ of corresponding plan views, respectively.

Referring to FIGS. 1 and 2, a first insulation layer 20 and a first sacrificial layer 30 may be alternately and repeatedly stacked in the first direction D1 on a first substrate 10 to form a first mold layer.

The first substrate 10 may include a semiconductor material, e.g., silicon, germanium, silicon-germanium, etc., or a III-V group compound semiconductor, e.g., GaP, GaAs, GaSb, etc. In some example embodiments, the first substrate 10 may be a silicon-on-insulator (SOI) substrate or a germanium-on-insulator (GOI) substrate.

In example embodiments, the first insulation layer 20 may include an oxide, e.g., silicon oxide, and the first sacrificial layer 30 may include a material having an etching selectivity with respect to the first insulation layer 20, e.g., an insulating nitride such as silicon nitride.

A first photoresist pattern may be formed on a first one of the first insulation layers 20, which may be disposed at an uppermost level among the first insulation layers 20, and a first etching process may be performed using the first photoresist pattern as an etching mask to partially remove two upper layers of the first mold layer, that is, the first one of the first insulation layers 20 and a first one of the first sacrificial layers 30, which may be disposed at an uppermost level among the first sacrificial layers 30, and thus first to eighth holes 41, 42, 43, 44, 45, 46, 47 and 48 spaced apart from each other in the second direction D2 may be formed.

Each of the first to eighth holes 41, 42, 43, 44, 45, 46, 47 and 48 may expose an upper surface of a second one of the first insulation layers 20 that is disposed at a second level from above among the first insulation layers 20.

In example embodiments, each of the first to eighth holes 41, 42, 43, 44, 45, 46, 47 and 48 may have a first width W1 in the horizontal direction (i.e., any direction in a plane formed by the directions D2 and D3) and a first depth P1 in the first direction D1 from an upper surface of the first one of the first insulation layers 20.

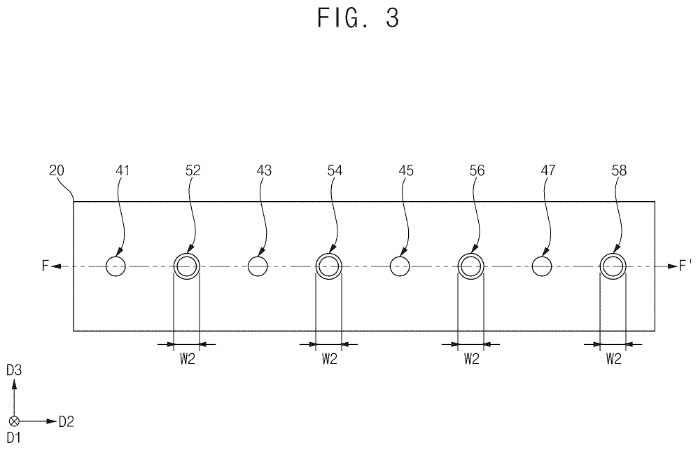

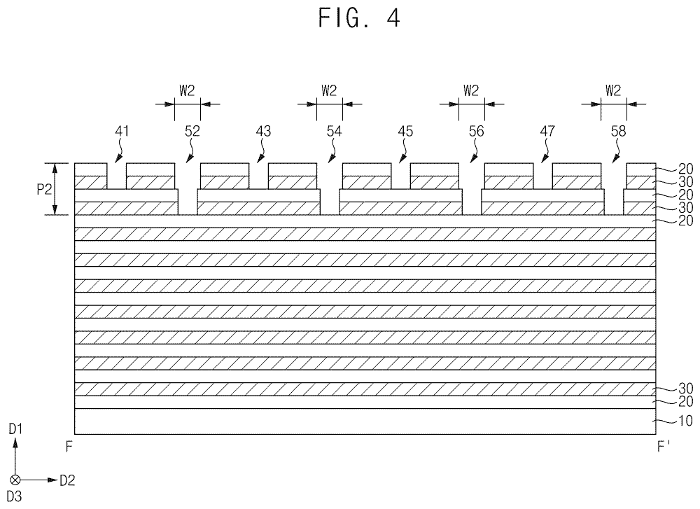

Referring to FIGS. 3 and 4, the first one of the first insulation layers 20, the second one of the first insulation layers 20, the first one of the first sacrificial layers 30, and a second one of the first sacrificial layers 30 that is disposed at a second level from above among the first sacrificial layers 30 may be partially removed to form ninth to twelfth holes 52, 54, 56 and 58 that are spaced apart from each other in the second direction D2 and expose an upper surface of a third one of the first insulation layers 20 disposed at a third level from above among the first insulation layers 20.

Components or layers described with reference to “overlap” in a particular direction may be at least partially obstructed by one another when viewed along a line extending in the particular direction or in a plane perpendicular to the particular direction.

In example embodiments, the ninth to twelfth holes 52, 54, 56 and 58 may be formed by performing a second etching process using a second photoresist pattern as an etching mask that may expose portions of the upper surface of the first one of the first insulation layers 20 adjacent to even-numbered ones among the first to eighth holes 41, 42, 43, 44, 45, 46, 47 and 48, that is, the second, fourth, sixth and eighth holes 42, 44, 46 and 48, respectively, on two upper layers of the first mold layer that do not overlap the second photoresist pattern in the first direction D1, which are the first one of the first insulation layers 20 and the first one of the first sacrificial layers 30, and on two upper layers of the first mold layer that are under the second, fourth, sixth and eighth holes 42, 44, 46 and 48, which are the second one of the first insulation layers 20 and the second one of the first sacrificial layers 30.

Thus, each of the ninth to twelfth holes 52, 54, 56 and 58 may include a lower portion having the first width W1 and extending through the second one of the first insulation layers 20 and the second one of the first sacrificial layers 30, and an upper portion having a second width W2 greater than the first width W1 and extending through the first one of the first insulation layers 20 and the first one of the first sacrificial layers 30. Each of the ninth to twelfth holes 52, 54, 56 and 58 may have a second depth P2 in the first direction D1 from the upper surface of the first one of the first insulation layers 20, which may be greater than the first depth P1.

As the ninth to twelfth holes 52, 54, 56 and 58 are formed, the first, ninth, third, tenth, fifth, eleventh, seventh and twelfth holes 41, 52, 43, 54, 45, 56, 47 and 58 may be formed to be spaced apart from each other in the second direction D2 in this order.

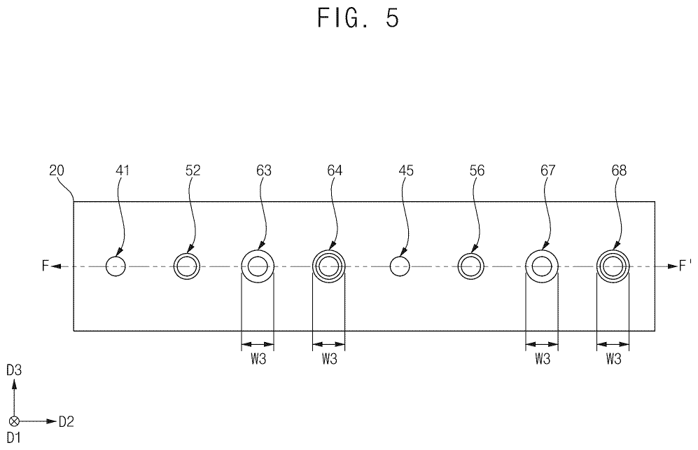

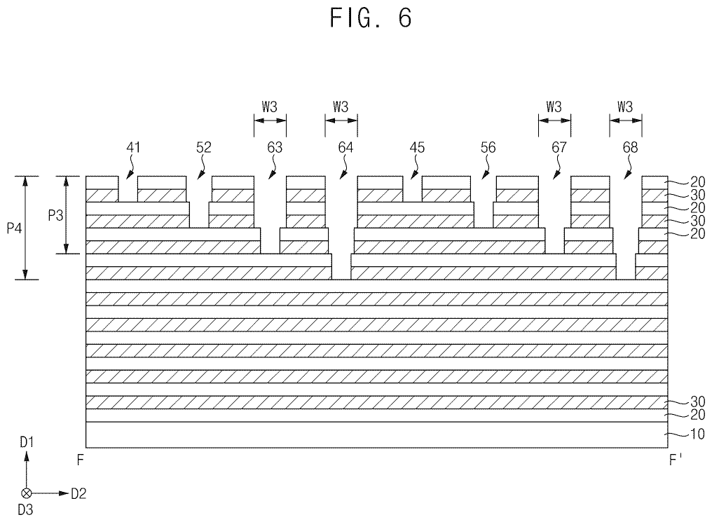

Referring to FIGS. 5 and 6, the first and second ones of the first insulation layers 20, third and fourth ones of the first insulation layers 20 that are disposed at third and fourth levels, respectively, from above among the first insulation layers 20, the first and second ones of the first sacrificial layers 30, and third and fourth ones of the first sacrificial layers 30 that are disposed at third and fourth levels, respectively, from above among the first sacrificial layers 30 may be partially removed to form thirteenth to sixteenth holes 63, 64, 67 and 68 that are spaced apart from each other in the second direction D2 and expose an upper surface of the fourth one of the first insulation layers 20 or an upper surface of a fifth one of the first insulation layers 20 disposed at a fifth level from above among the first insulation layers 20.

In example embodiments, the thirteenth to sixteenth holes 63, 64, 67 and 68 may be formed by performing a third etching process using a third photoresist pattern as an etching mask that may expose portions of the upper surface of the first one of the first insulation layers 20 adjacent to third, fourth, seventh and eighth ones among the first, ninth, third, tenth, fifth, eleventh, seventh and twelfth holes 41, 52, 43, 54, 45, 56, 47 and 58, that is, the third, tenth, seventh and twelfth holes 43, 54, 47 and 58, respectively, on four upper layers of the first mold layer that do not overlap the third photoresist pattern in the first direction D1, which are the first and second ones of the first insulation layers 20 and the first and second ones of the first sacrificial layers 30, on four upper layers of the first mold layer that are under the third, tenth, seventh and twelfth holes 43, 54, 47 and 58, which are the second and third ones or the third and fourth ones of the first insulation layers 20 and the second and third ones or the third and fourth ones of the first sacrificial layers 30, and on four upper layers of the first mold layer that are under the upper portions of the tenth and twelfth holes 54 and 58, which are the second and third ones of the first insulation layers 20 and the second and third ones of the first sacrificial layers 30.

Thus, each of the thirteenth and fifteenth holes 63 and 67 may include a lower portion having the first width W1 and extending through the third one of the first insulation layers 20 and the third one of the first sacrificial layers 30, and an upper portion having a third width W3 greater than the second width W2 and extending through the first and second ones of the first insulation layers 20 and the first and second ones of the first sacrificial layers 30. Each of the thirteenth and fifteenth holes 63 and 67 may have a third depth P3 in the first direction D1 from the upper surface of the first one of the first insulation layers 20, which may be greater than the second depth P2.

Additionally, each of the fourteenth and sixteenth holes 64 and 68 may include a lower portion having the first width W1 and extending through the fourth one of the first insulation layers 20 and the fourth one of the first sacrificial layers 30, a middle portion having the second width W2 and extending through the third one of the first insulation layers 20 and the third one of the first sacrificial layers 30, and an upper portion having the third width W3 and extending through the first and second ones of the first insulation layers 20 and the first and second ones of the first sacrificial layers 30. Each of the fourteenth and sixteenth holes 64 and 68 may have a fourth depth P4 in the first direction D1 from the upper surface of the first one of the first insulation layers 20, which may be greater than the third depth P3.

As the thirteenth to sixteenth holes 63, 64, 67 and 68 are formed, the first, ninth, thirteenth, fourteenth, fifth, eleventh, fifteenth and sixteenth holes 41, 52, 63, 64, 45, 56, 67 and 68 may be formed to be spaced apart from each other in the second direction D2 in this order.

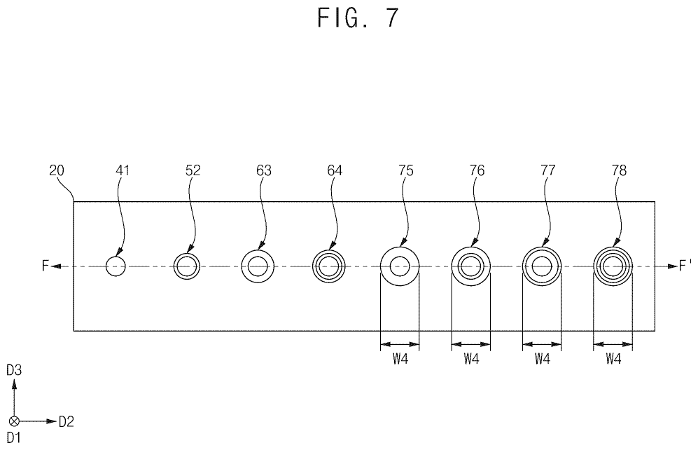

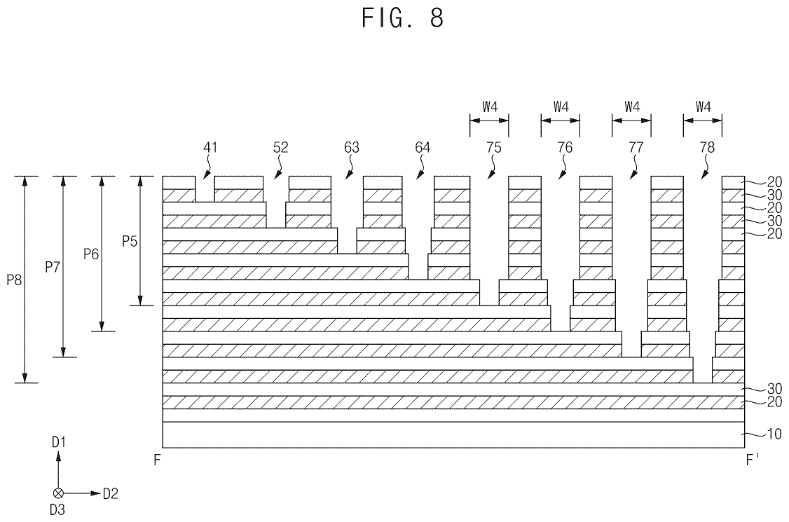

Referring to FIGS. 7 and 8, the first to fourth ones of the first insulation layers 20, fifth to eighth ones of the first insulation layers 20 that are disposed at fifth to eighth levels, respectively, from above among the first insulation layers 20, the first to fourth ones of the first sacrificial layers 30, and fifth to eighth ones of the first sacrificial layers 30 that are disposed at fifth to eighth levels, respectively, from above among the first sacrificial layers 30 may be partially removed to form seventeenth to twentieth holes 75, 76, 77 and 78 spaced apart from each other in the second direction D2 and exposing an upper surface of one of the sixth to ninth ones of the first insulation layers 20 that is disposed at one of the sixth to ninth levels from above among the first insulation layers 20.

In example embodiments, the seventeenth to twentieth holes 75, 76, 77 and 78 may be formed by performing a fourth etching process using a fourth photoresist pattern as an etching mask that may expose portions of the upper surface of the first one of the first insulation layers 20 adjacent to fifth, sixth, seventh and eighth ones among the first, ninth, thirteenth, fourteenth, fifth, eleventh, fifteenth and sixteenth holes 41, 52, 63, 64, 45, 56, 67 and 68, that is, the fifth, eleventh, fifteenth and sixteenth holes 45, 56, 67 and 68, respectively, on eight upper layers of the first mold layer that do not overlap the fourth photoresist pattern in the first direction D1, which are the first to fourth ones of the first insulation layers 20 and the first to fourth ones of the first sacrificial layers 30, on eight upper layers of the first mold layer that are under the fifth, eleventh, fifteenth and sixteenth holes 45, 56, 67 and 68, which are the second to fifth ones, the third to sixth ones, the fourth to seventh ones, or the fifth to eighth ones of the first insulation layers 20 and the second to fifth ones, the third to sixth ones, the fourth to seventh ones, or the fifth to eighth ones of the first sacrificial layers 30, on eight upper layers of the first mold layer that are under the upper portion of the eleventh hole 56, which are the second to fifth ones of the first insulation layers 20 and the second to fifth ones of the first sacrificial layers 30, on eight upper layers of the first mold layer that are under the upper portion of the fifteenth hole 67, which are the third to sixth ones of the first insulation layers 20 and the third to sixth ones of the first sacrificial layers 30, on eight upper layers of the first mold layer that are under the upper portion of the sixteenth hole 68, which are the third to sixth ones of the first insulation layers 20 and the third to sixth ones of the first sacrificial layers 30, and on eight upper layers of the first mold layer that are under the middle portion of the sixteenth hole 68, which are the fourth to seventh ones of the first insulation layers 20 and the fourth to seventh ones of the first sacrificial layers 30.

Thus, the seventeenth hole 75 may include a lower portion having the first width W1 and extending through the fifth one of the first insulation layers 20 and the fifth one of the first sacrificial layers 30, and an upper portion having a fourth width W4 greater than the third width W3 and extending through the second to fourth ones of the first insulation layers 20 and the second to fourth ones of the first sacrificial layers 30. The seventeenth hole 75 may have a fifth depth P5 in the first direction D1 from the upper surface of the first one of the first insulation layers 20, which may be greater than the fourth depth P4.

Additionally, the eighteenth hole 76 may include a lower portion having the first width W1 and extending through the sixth one of the first insulation layers 20 and the sixth one of the first sacrificial layers 30, a middle portion having the second width W2 and extending through the fifth one of the first insulation layers 20 and the fifth one of the first sacrificial layers 30, and an upper portion having the fourth width W4 and extending through the first to fourth ones of the first insulation layers 20 and the first to fourth ones of the first sacrificial layers 30. The eighteenth hole 76 may have a sixth depth P6 in the first direction D1 from the upper surface of the first one of the first insulation layers 20, which may be greater than the fifth depth P5.

The nineteenth hole 77 may include a lower portion having the first width W1 and extending through the seventh one of the first insulation layers 20 and the seventh one of the first sacrificial layers 30, a middle portion having the third width W3 and extending through the fifth and sixth ones of the first insulation layers 20 and the fifth and sixth ones of the first sacrificial layers 30, and an upper portion having the fourth width W4 and extending through the first to fourth ones of the first insulation layers 20 and the first to fourth ones of the first sacrificial layers 30. The nineteenth hole 77 may have a seventh depth P7 in the first direction D1 from the upper surface of the first one of the first insulation layers 20, which may be greater than the sixth depth P6.

The twentieth hole 78 may include a lower portion having the first width W1 and extending through the eighth one of the first insulation layers 20 and the eighth one of the first sacrificial layers 30, a first middle portion having the second width W2 and extending through the seventh one of the first insulation layers 20 and the seventh one of the first sacrificial layers 30, a second middle portion having the third width W3 and extending through the fifth to sixth ones of the first insulation layers 20 and the fifth to sixth ones of the first sacrificial layers 30, and an upper portion having the fourth width W4 and extending through the first to fourth ones of the first insulation layers 20 and the first to fourth ones of the first sacrificial layers 30. The twentieth hole 78 may have an eighth depth P8 in the first direction D1 from the upper surface of the first one of the first insulation layers 20, which may be greater than the seventh depth P7.

As the seventeenth to twentieth holes 75, 76, 77 and 78 are formed, the first, ninth, thirteenth, fourteenth, seventeenth, eighteenth, nineteenth and twentieth holes 41, 52, 63, 64, 75, 76, 77 and 78 may be formed to be spaced apart from each other in the second direction D2 in this order.

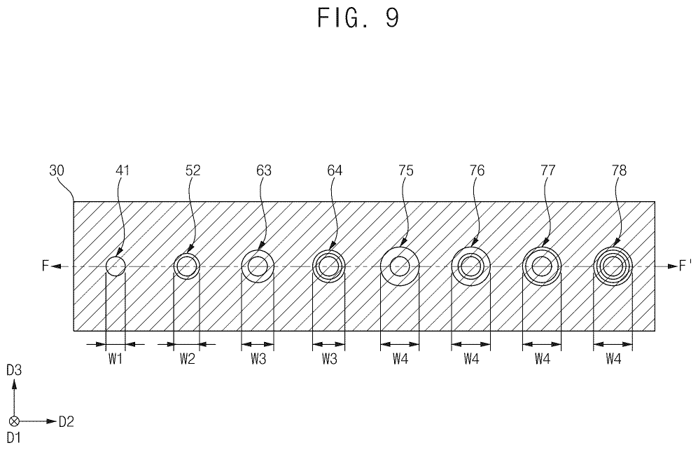

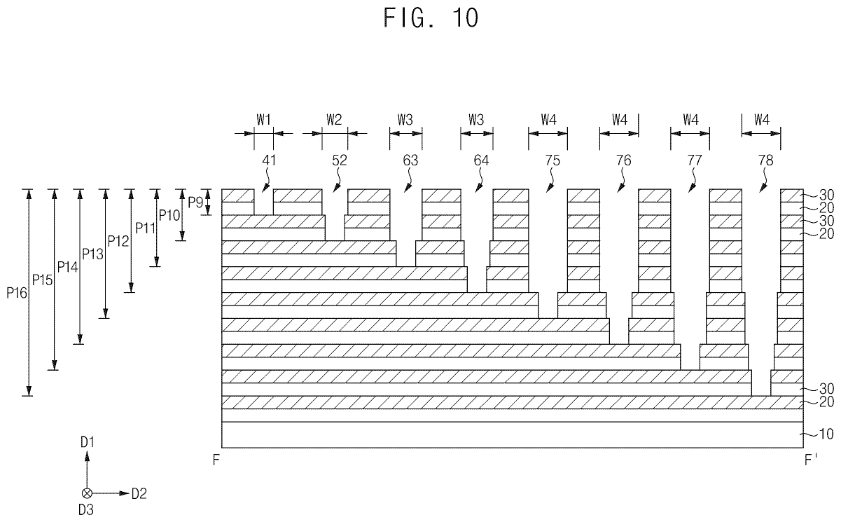

Referring to FIGS. 9 and 10, a fifth etching process may be performed on the first insulation layers 20 included in the first mold layer.

In example embodiments, the fifth etching process may be performed on one upper layer of the first insulation layers 20 without an etching mask. Thus, the first one of the first insulation layers 20 may be removed, and portions of the first insulation layers 20 exposed by the first, ninth, thirteenth, fourteenth, seventeenth, eighteenth, nineteenth and twentieth holes 41, 52, 63, 64, 75, 76, 77 and 78 may also be removed to expose upper surfaces of portions of the first sacrificial layers 30 under the portions of the first insulation layers 20.

Thus, the first, ninth, thirteenth, fourteenth, seventeenth, eighteenth, nineteenth and twentieth holes 41, 52, 63, 64, 75, 76, 77 and 78 may partially extend through the first mold layer on the first substrate 10 and may be spaced apart from each other in the second direction D2. The first, ninth, thirteenth, fourteenth, seventeenth, eighteenth, nineteenth and twentieth holes 41, 52, 63, 64, 75, 76, 77 and 78 may have ninth to sixteenth depths P9, P10, P11, P12, P13, P14, P15 and P16, respectively, which may increase in the second direction D2 in this order. Top ends of the first, ninth, thirteenth, fourteenth, seventeenth, eighteenth, nineteenth and twentieth holes 41, 52, 63, 64, 75, 76, 77 and 78 may have the first to fourth widths W1, W2, W3 and W4.

When the first sacrificial layers 30 are replaced with gate electrodes including a conductive material, an insulating spacer is formed on sidewalls of the first, ninth, thirteenth, fourteenth, seventeenth, eighteenth, nineteenth and twentieth holes 41, 52, 63, 64, 75, 76, 77 and 78, and contact plugs are formed in other portions of the first, ninth, thirteenth, fourteenth, seventeenth, eighteenth, nineteenth and twentieth holes 41, 52, 63, 64, 75, 76, 77 and 78, each of the contact plugs may contact an upper surface of only one of gate electrodes among the gate electrodes to be electrically connected thereto, but may be electrically insulated from other ones of the gate electrodes.

In example embodiments, each of the first, ninth, thirteenth, fourteenth, seventeenth, eighteenth, nineteenth and twentieth holes 41, 52, 63, 64, 75, 76, 77 and 78 may have a width decreasing in the first direction D1 from a top toward a bottom thereof in a stepwise manner.

In example embodiments, eight holes, that is, the first to eighth holes 41, 42, 43, 44, 45, 46, 47 and 48 extending through the first one of the first insulation layers 20 and the first one of the first sacrificial layers 30 may be formed by the first etching process, the second etching process may be performed on upper two layers, that is, one of the first insulation layers 20 at one level and one of the first sacrificial layers 30 at one level, the third etching process may be performed on upper four layers, that is, ones of the first insulation layers 20 at two levels, respectively, and ones of the first sacrificial layers 30 at two levels, respectively, the third etching process may be performed on upper four layers, that is, ones of the first insulation layers 20 at three levels, respectively, and ones of the first sacrificial layers 30 at three levels, respectively, the fourth etching process may be performed on upper eight layers, that is, ones of the first insulation layers 20 at four levels, respectively, and ones of the first sacrificial layers 30 at four levels, respectively, and the fifth etching process may be performed on the first insulation layers 20, so that eight holes 41, 52, 63, 64, 75, 76, 77 and 79 spaced apart from each other in the second direction D2 may be formed to expose upper surfaces of ones of the first sacrificial layers 30 at different levels from each other, however, the inventive concept is not limited thereto.

For example, the eight holes, that is, the first to eighth holes 41, 42, 43, 44, 45, 46, 47 and 48 may be defined as a hole group, eight hole groups spaced apart from each other in the horizontal direction, e.g., in the second direction D2 or in the first direction D1 may be formed in the first mold layer, and the second to fifth etching processes may be performed on the eight hole groups, so that sixty-four holes exposing sixty-four first sacrificial layers 30 at different levels, respectively, in the first mold layer may be formed.

Thus, 8ⁿ (n is a natural number) holes, which may be spaced apart from each other in the horizontal direction, may be formed to expose upper surfaces of 8ⁿ first sacrificial layers 30 at different levels, respectively, included in the first mold layer. Alternatively, the number of the holes included in each hole group or the number of the hole groups may be controlled, so that 2″ holes, which may be spaced apart from each other in the horizontal direction, may be formed to expose upper surfaces of 2ⁿ first sacrificial layers 30 at different levels, respectively, included in the first mold layer.

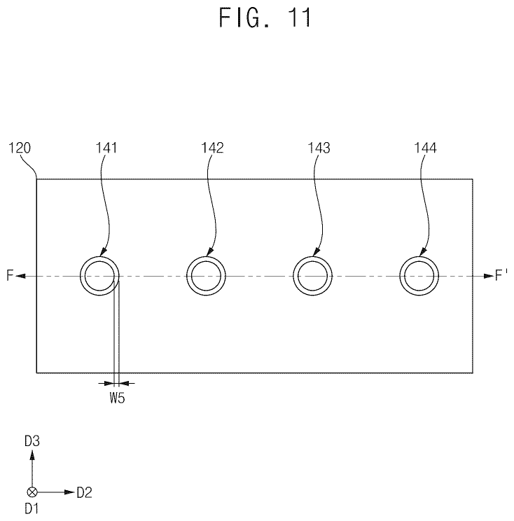

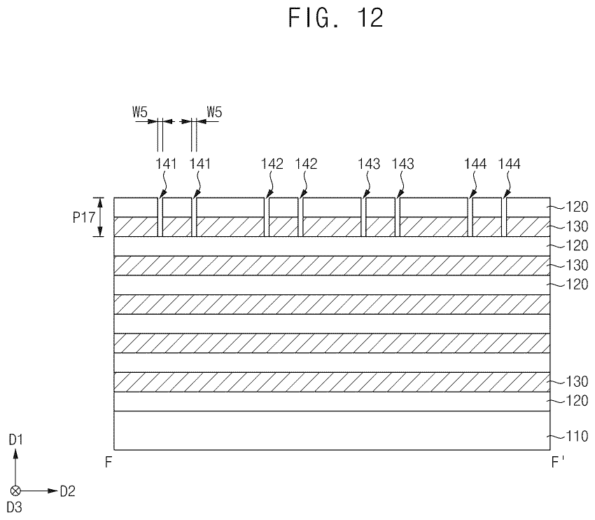

FIGS. 11 to 18 are plan views and cross-sectional views illustrating a method of forming a hole in accordance with example embodiments. Specifically, FIGS. 11, 13, 15 and 17 are the plan views, and FIGS. 12, 14, 16 and 18 are cross-sectional views taken along lines F-F′ of corresponding plan views, respectively.

This method may be substantially the same as or similar to the method illustrated with reference to FIGS. 1 to 10, except for the shape of the hole, and thus repeated explanations are omitted herein.

FIGS. 11 to 18 show holes that expose upper surfaces of four sacrificial layers at four levels, respectively, however, the inventive concept is not limited thereto, and as illustrated above, for example, 2ⁿ holes exposing upper surfaces of 2ⁿ sacrificial layers at 2ⁿ levels, respectively, may be formed.

Referring to FIGS. 11 and 12, a second insulation layer 120 and a second sacrificial layer 130 may be alternately and repeatedly stacked on a second substrate 110 to form a second mold layer.

A fifth photoresist pattern may be formed on an uppermost one, that is, a first one of the second insulation layers 120, a sixth etching process may be performed using the fifth photoresist pattern as an etching mask to partially etch the first one of the second insulation layers 120 and an uppermost one, that is, a first one of the second sacrificial layers 130, and thus twenty-first to twenty-fourth holes 141, 142, 143 and 144 exposing an upper surface of a second one of the second insulation layers 120 disposed at a second level from above may be formed to be spaced apart from each other in the second direction D2.

In example embodiments, each of the twenty-first to twenty-fourth holes 141, 142, 143 and 144 may have a shape of a circular ring in a plan view. The circular ring may have a fifth width W5 in the horizontal direction, and may have a seventeenth depth P17 in the first direction D1 from an upper surface of the first one of the second insulation layers 120.

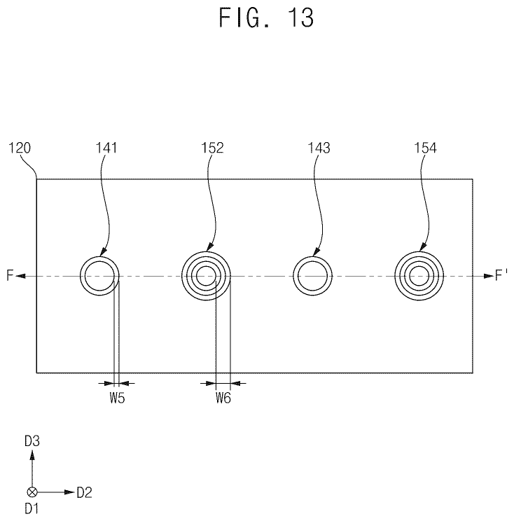

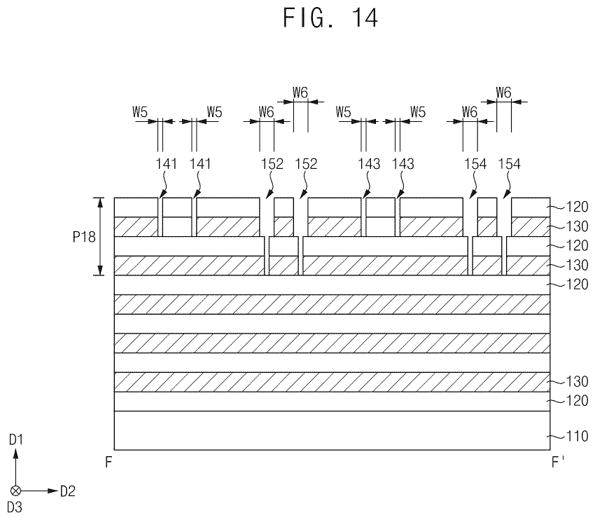

Referring to FIGS. 13 and 14, the first one of the second insulation layers 120, the second one of the second insulation layers 120, the first one of the second sacrificial layers 130, and a second one of the second sacrificial layers 130 that is disposed at a second level from above may be partially removed to form twenty-fifth and twenty-sixth holes 152 and 154 that are spaced apart from each other in the second direction D2 and expose an upper surface of a third one of the second insulation layers 120 disposed at a third level from above.

In example embodiments, the twenty-fifth and twenty-sixth holes 152 and 154 may be formed by performing a seventh etching process using a sixth photoresist pattern as an etching mask that may expose portions of the upper surface of the first one of the second insulation layers 120 adjacent to even-numbered ones among the twenty-first to twenty-fourth holes 141, 142, 143 and 144, that is, the twenty-second and twenty-fourth holes 142 and 144, respectively, on two upper layers of the second mold layer that do not overlap the sixth photoresist pattern in the first direction D1, which are the first one of the second insulation layers 120 and the first one of the second sacrificial layers 130, and on two upper layers of the second mold layer that are under the twenty-second and twenty-fourth holes 142 and 144, which are the second one of the second insulation layers 120 and the second one of the second sacrificial layers 130.

Thus, each of the twenty-fifth and twenty-sixth holes 152 and 154 may include a lower portion having the fifth width W5 and extending through the second one of the second insulation layers 120 and the second one of the second sacrificial layers 130, and an upper portion having a sixth width W6 greater than the fifth width W5 and extending through the first one of the second insulation layers 120 and the first one of the second sacrificial layers 130. Each of the twenty-fifth and twenty-sixth holes 152 and 154 may have an eighteenth depth P18 in the first direction D1 from the upper surface of the first one of the second insulation layers 120, which may be greater than the seventeenth depth P17.

As the twenty-fifth and twenty-sixth holes 152 and 154 are formed, the twenty-first, twenty-fifth, twenty-third and twenty-sixth holes 141, 152, 143 and 154 may be formed to be spaced apart from each other in the second direction D2 in this order.

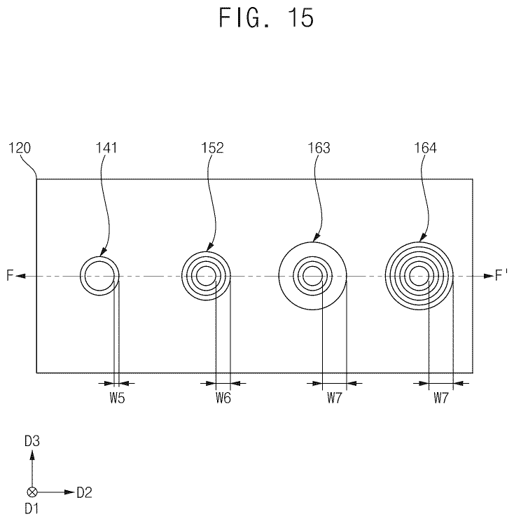

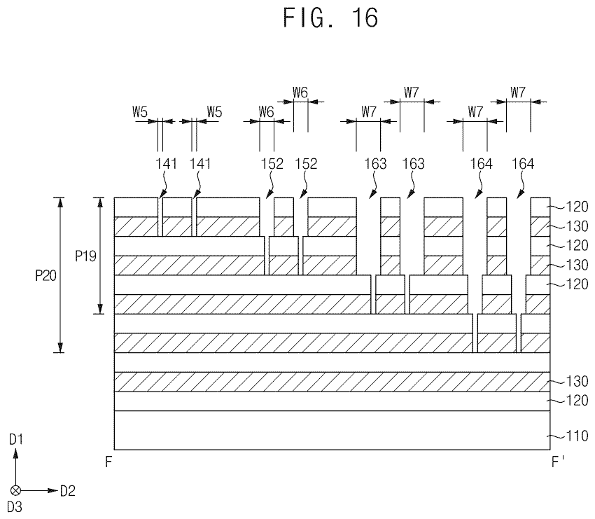

Referring to FIGS. 15 and 16, the first and second ones of the second insulation layers 120, third and fourth ones of the second insulation layers 120 that are disposed at third and fourth levels, respectively, from above, the first and second ones of the second sacrificial layers 130, and third and fourth ones of the second sacrificial layers 130 that are disposed at third and fourth levels, respectively, from above may be partially removed to form twenty-seventh and twenty-eighth holes 163 and 164 that are spaced apart from each other in the second direction D2 and expose an upper surface of the fourth one of the second insulation layers 120 or an upper surface of a fifth one of the second insulation layers 120 disposed at a fifth level from above.

In example embodiments, the twenty-seventh and twenty-eighth holes 163 and 164 may be formed by performing an eighth etching process using a seventh photoresist pattern as an etching mask that may expose portions of the upper surface of the first one of the second insulation layers 120 adjacent to third and fourth ones among the twenty-first, twenty-fifth, twenty-third and twenty-sixth holes 141, 152, 143 and 154, that is, the twenty-third and twenty-sixth holes 143 and 154, respectively, on four upper layers of the second mold layer that do not overlap the seventh photoresist pattern in the first direction D1, which are the first and second ones of the second insulation layers 120 and the first and second ones of the second sacrificial layers 130, on four upper layers of the second mold layer that are under the twenty-third and twenty-sixth holes 143 and 154, which are the second and third ones of the second insulation layers 120 and the second and third ones of the second sacrificial layers 130, and on four upper layers of the second mold layer that are under the upper portion of the twenty-sixth hole 154, which are the second and third ones of the second insulation layers 120 and the second and third ones of the second sacrificial layers 130.

Thus, the twenty-seventh hole 163 may include a lower portion having the fifth width W5 and extending through the third one of the second insulation layers 120 and the third one of the second sacrificial layers 130, and an upper portion having a seventh width W7 greater than the sixth width W6 and extending through the first and second ones of the second insulation layers 120 and the first and second ones of the second sacrificial layers 130. The twenty-seventh hole 163 may have a nineteenth depth P19 in the first direction D1 from the upper surface of the first one of the second insulation layers 120, which may be greater than the eighteenth depth P18.

Additionally, the twenty-eighth hole 164 may include a lower portion having the fifth width W1 and extending through the fourth one of the second insulation layers 120 and the fourth one of the second sacrificial layers 130, a middle portion having the sixth width W6 and extending through the third one of the second insulation layers 120 and the third one of the second sacrificial layers 130, and an upper portion having the seventh width W7 and extending through the first and second ones of the second insulation layers 120 and the first and second ones of the second sacrificial layers 130. The twenty-eighth hole 164 may have a twentieth depth P20 in the first direction D1 from the upper surface of the first one of the second insulation layers 120, which may be greater than the nineteenth depth P19.

As the twenty-seventh and twenty-eighth holes 163 and 164 are formed, the twenty-first, twenty-fifth, twenty-seventh and twenty-eighth holes 141, 152, 163 and 164 may be formed to be spaced apart from each other in the second direction D2 in this order.

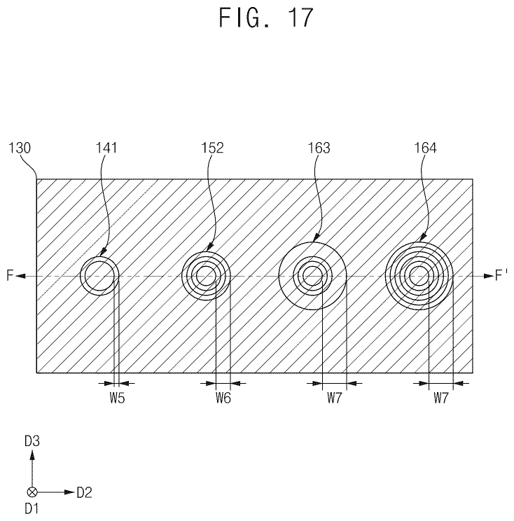

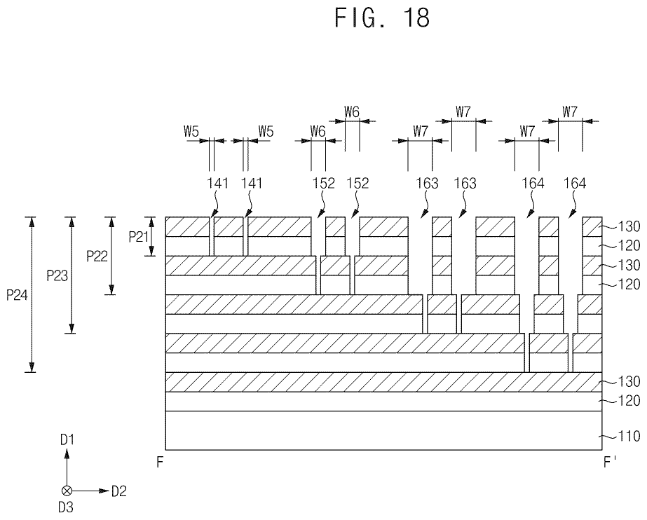

Referring to FIGS. 17 and 18, a ninth etching process may be performed on the second insulation layers 120 included in the second mold layer.

In example embodiments, the ninth etching process may be performed on one upper layer of the second insulation layers 120 without an etching mask. Thus, the first one of the second insulation layers 120 may be removed, and portions of the second insulation layers 120 exposed by the twenty-first, twenty-fifth, twenty-seventh and twenty-eighth holes 141, 152, 163 and 164 may also be removed to expose upper surfaces of portions of the second sacrificial layers 130 under the portions of the second insulation layers 120.

Thus, the twenty-first, twenty-fifth, twenty-seventh and twenty-eighth holes 141, 152, 163 and 164 may partially extend through the second mold layer on the second substrate 110 and may be spaced apart from each other in the second direction D2. The twenty-first, twenty-fifth, twenty-seventh and twenty-eighth holes 141, 152, 163 and 164 may have twenty-first to twenty-fourth depths P21, P22, P23 and P24, respectively, which may increase in the second direction D2 in this order. Top ends of the twenty-first, twenty-fifth, twenty-seventh and twenty-eighth holes 141, 152, 163 and 164 may have the fifth to seventh widths W5, W6 and W7.

When the second sacrificial layers 130 are replaced with gate electrodes including a conductive material, an insulating spacer is formed on sidewalls of the twenty-first, twenty-fifth, twenty-seventh and twenty-eighth holes 141, 152, 163 and 164, and contact plugs are formed in other portions of the twenty-first, twenty-fifth, twenty-seventh and twenty-eighth holes 141, 152, 163 and 164, each of the contact plugs may contact an upper surface of only one of gate electrodes among the gate electrodes to be electrically connected thereto, but may be electrically insulated from other ones of the gate electrodes.

In example embodiments, each of the twenty-first, twenty-fifth, twenty-seventh and twenty-eighth holes 141, 152, 163 and 164 may have a width decreasing in the first direction D1 from a top toward a bottom thereof in a stepwise manner.

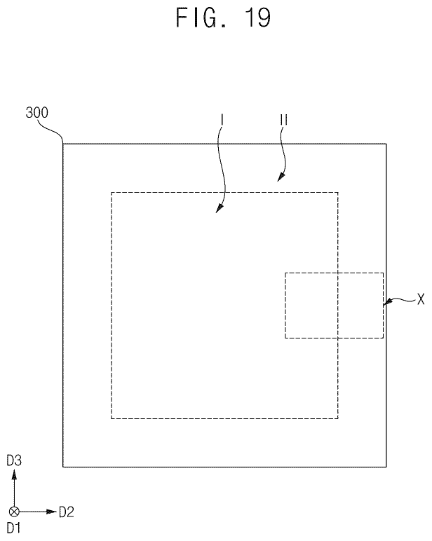

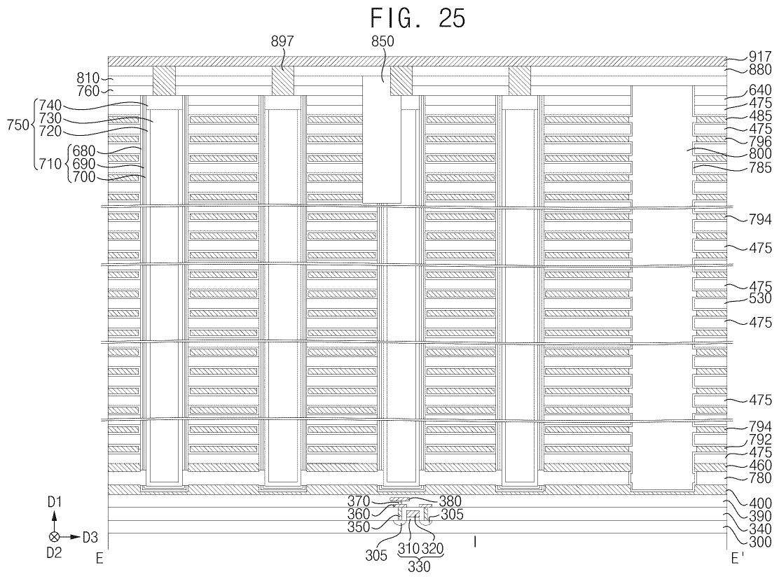

FIGS. 19 to 25 are plan views and cross-sectional views illustrating a semiconductor device in accordance with example embodiments.

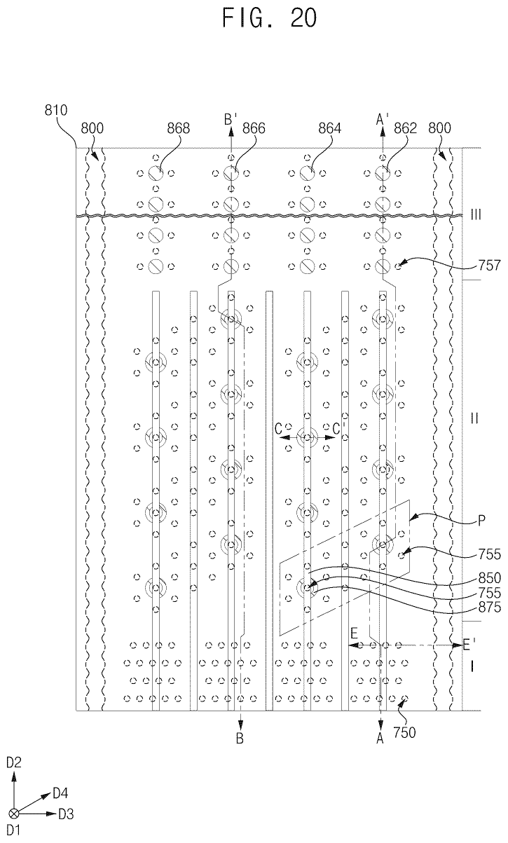

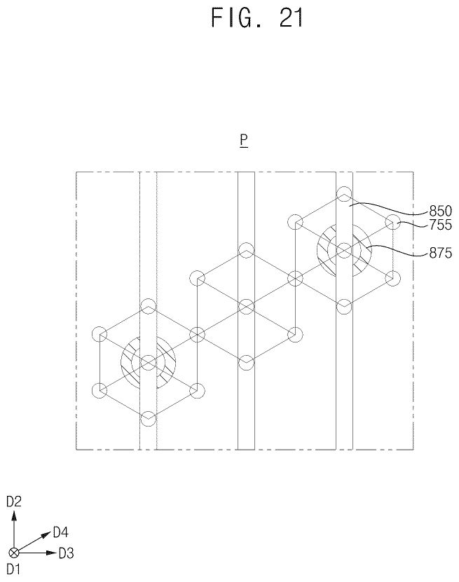

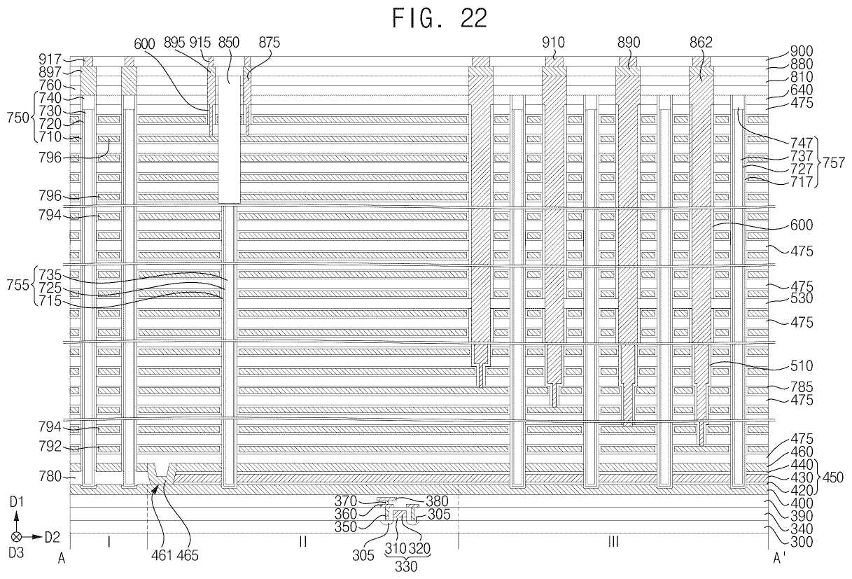

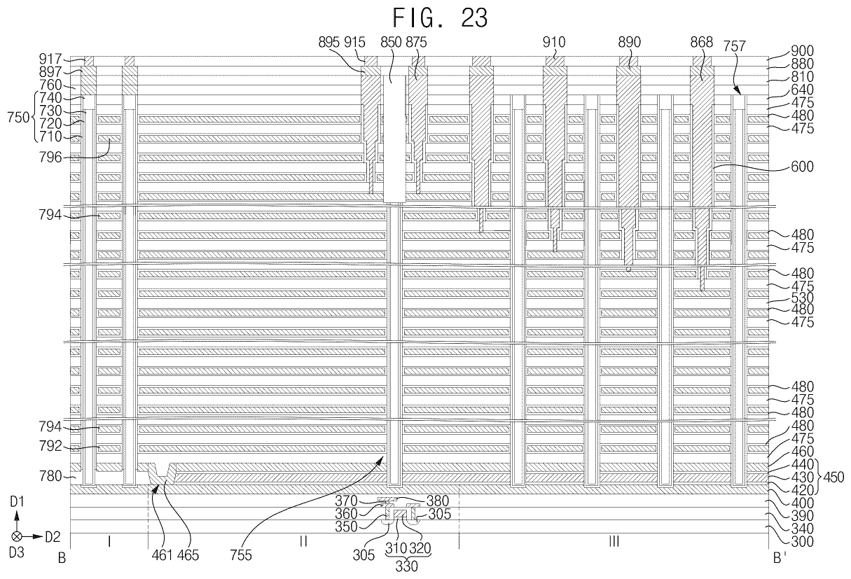

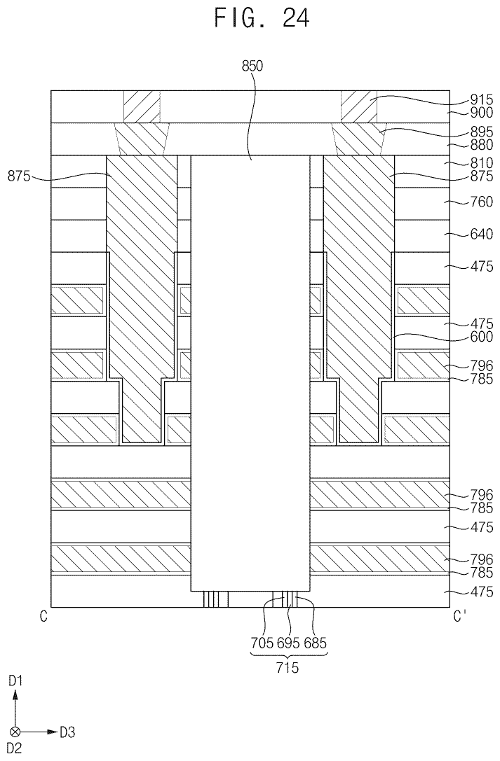

Particularly, FIGS. 19 to 21 are the plan views, FIG. 22 is a cross-sectional view taken along line A-A′ of FIG. 20, FIG. 23 is a cross-sectional view taken along line B-B′ of FIG. 20, and FIG. 24 is a cross-sectional view taken along line C-C′ of FIG. 20. FIG. 21 is a drawing illustrating a layout of fifth upper contact plugs, first support structures and a second division pattern arranged in a region P of FIG. 20, and FIGS. 20 to 25 are drawings about region X of FIG. 19.

FIG. 20 does not show upper wirings and upper vias in order to avoid complexity of the drawing.

Referring to FIGS. 19 to 25, the semiconductor device may include a lower circuit pattern, a common source plate (CSP) 400, a gate electrode structure, a first memory channel structure 750, first and second support structures 755 and 757, first and second division patterns 800 and 850, first to fifth upper contact plugs 862, 864, 866, 868 and 875, first and second spacers 510 and 600, first to third upper vias 890, 895 and 897, and first to third upper wirings 910, 915 and 917 on a third substrate 300.

In addition, the semiconductor device may include a sacrificial layer structure 450, a support layer 460, a support pattern 465, a channel connection pattern 780, a fourth blocking pattern 785, a third insulation pattern 475, and first to sixth upper insulating interlayers 530, 640, 760, 810, 880 and 900.

The third substrate 300 may include a semiconductor material, e.g., silicon, germanium, silicon-germanium, etc., or a III-V group compound semiconductor, e.g., GaP, GaAs, GaSb, etc. In some example embodiments, the third substrate 300 may be an SOI substrate or a GOI substrate.

The third substrate 300 may include first, second and third regions I, II and III. In example embodiments, the first region I of the third substrate 300 may be a cell array region in which memory cells are formed, the second region II of the third substrate 300 may be an extension region in which upper contact plugs for transferring electrical signals to word lines and ground selection lines (GSLs) connected to the memory cells are formed, and the third region III of the third substrate 300 may be a transition region in which upper contact plugs for transferring electrical signals to string selection lines (SSLs) connected to the memory cells are formed.

In example embodiments, the second region II may surround the first region I, or may be disposed at opposite sides in the second direction D2 of the first region I, and the third region III may surround the second region II, or may be disposed at opposite sides in the second direction D2 of the second region II.

In example embodiments, the semiconductor device may have a cell over periphery (COP) structure. That is, the lower circuit pattern may be disposed on the third substrate 300, and the memory cells, the upper contact plugs and an upper circuit pattern may be disposed over the lower circuit pattern. The lower circuit pattern may include, e.g., lower transistors, lower contact plugs, lower wirings, lower vias, etc. However, the inventive concept may not be limited thereto, and the semiconductor device may not have the COP structure.

For example, the lower transistor may include a lower gate structure 330 on the third substrate 300 and impurity regions 305 at upper portions, respectively, of the third substrate 300 adjacent to the lower gate structure 330, which may serve as source/drains, respectively. The lower gate structure 330 may include a lower gate insulation pattern 310 and a lower gate electrode 320 sequentially stacked on the third substrate 300.

The first insulating interlayer 340 may be disposed on the third substrate 300, and may cover the lower transistor. A first lower contact plug 350 may extend through the first insulating interlayer 340 to contact each of the impurity regions 305. A second lower contact plug (not shown) may extend through the first insulating interlayer 340 to contact the lower gate electrode 320.

A first lower wiring 360 may be disposed on the first insulating interlayer 340, and may contact an upper surface of the first lower contact plug 350. A lower via 370 and a second lower wiring 380 may be sequentially stacked on the first lower wiring 360.

The second lower insulating interlayer 390 may be disposed on the first insulating interlayer 340, and may cover the first to third lower wirings 360 and 380 and the lower via 370.

The CSP 400 may be disposed on the second lower insulating interlayer 390. The CSP 400 may include, e.g., polysilicon doped with n-type impurities. Alternatively, the CSP 400 may include a metal silicide layer and a polysilicon layer doped with n-type impurities sequentially stacked. The metal silicide layer may include, e.g., tungsten silicide.

The sacrificial layer structure 450, the channel connection pattern 780, the support layer 460 and the support pattern 465 may be disposed on the CSP 400.

The channel connection pattern 780 may be disposed on the first region I of the third substrate 300, and may include an air gap therein. The sacrificial layer structure 450 may be disposed on the second and third regions II and III of the third substrate 300.

The channel connection pattern 780 may include polysilicon doped with n-type impurities or undoped polysilicon. The sacrificial layer structure 450 may include third to fifth sacrificial layers 420, 430 and 440 sequentially stacked in the first direction D1. Each of the third and fifth sacrificial layers 420 and 440 may include an oxide, e.g., silicon oxide, and the fourth sacrificial layer 430 may include a nitride, e.g., silicon nitride.

The support layer 460 may be disposed on the channel connection pattern 780 and the sacrificial layer structure 450, and may also be disposed in a first opening 461 extending through the channel connection pattern 780 and the sacrificial layer structure 450 to expose an upper surface of the CSP 400, which may be referred to as the support pattern 465.

The support pattern 465 may have various layouts in a plan view. In example embodiments, a plurality of support patterns 465 may be spaced apart from each other in each of the second and third directions D2 and D3 on the first region I of the third substrate 300. Additionally, the support pattern 465 may surround the first region I of the third substrate 300 on a portion of the second region II of the third substrate 300 adjacent to the first region I of the third substrate 300, and may have a shape of a rectangular ring in a plan view. Further, a plurality of support patterns 465, each of which may extend in the second direction D2, may be spaced apart from each other in the third direction D3 on the second and third regions II and III of the third substrate 300.

Each of the support layer 460 and the support pattern 465 may include a material having an etching selectivity with respect to the third to fifth sacrificial layers 420, 430 and 440, e.g., polysilicon doped with n-type impurities.

The gate electrode structure may include first, second and third gate electrodes 792, 794 and 796, which may be formed at a plurality of levels, respectively, spaced apart from each other in the first direction D1 on the support layer 460 and the support pattern 465, and each of the first, second and third gate electrodes 792, 794 and 796 may extend in the second direction D2. The first, second and third gate electrodes 792, 794 and 796 may be sequentially stacked in the first direction D1 upwardly.

In example embodiments, the first gate electrode 792 may serve as the GSL, the second gate electrode 794 may serve as the word line, and the third gate electrode 796 may serve as the SSL. In example embodiments, the first gate electrode 792 may be disposed, e.g., at one or two levels, the second gate electrode 794 may be disposed at a plurality of levels, and the third gate electrode 796 may be disposed, e.g., at two to four levels.

GIDL gate electrodes, which may be used for erasing data stored in the first memory channel structure 750 using a gate induced drain leakage (GIDL) phenomenon, may be disposed at one or a plurality of levels under or over the first gate electrode 792.

Each of the first to third gate electrodes 792, 794 and 796 may include a gate conductive pattern and a gate barrier pattern covering a surface of the gate conductive pattern. The gate conductive pattern may include a metal having a low resistance, e.g., tungsten, titanium, tantalum, platinum, etc., and the gate barrier pattern may include a metal nitride, e.g., titanium nitride, tantalum nitride, etc.

The third insulation pattern 475 may be disposed between neighboring ones of the first to third gate electrodes 792, 794 and 796 in the first direction D1 and between the first gate electrode 792 and the support layer 460 or the support pattern 465. The third insulation pattern 475 may include an oxide, e.g., silicon oxide.

In example embodiments, each of the first to third gate electrodes 792, 794 and 796 included in the gate electrode structure may extend in the second direction D2 on the first to third regions I, II and III of the third substrate 300, and lengths in the second direction D2 of the first to third gate electrodes 792, 794 and 796 stacked in the first direction D1 may be substantially the same as each other.

In example embodiments, a thickness in the first direction D1 of each of the first to third gate electrodes 792, 794 and 796 may be substantially constant in the second direction D2, and thus, a thickness in the first direction D1 of an end portion in the second direction D2 of each of the first to third gate electrodes 792, 794 and 796 may be substantially the same as thicknesses in the first direction D1 of other portions thereof.

In example embodiments, a plurality of gate electrode structures may be spaced apart from each other in the third direction D3. The first division pattern 800 extending in the second direction D2 may be disposed between ones of the gate structures neighboring in the third direction D3 on the CSP 400 on the first to third regions I, II and III of the third substrate 300.

In example embodiments, the first division pattern 800 may extend through the first to third upper insulating interlayers 530, 640 and 760, the gate electrode structure, the third insulation pattern 475, the support layer 460, the support pattern 465 and the sacrificial layer structure 450. In example embodiments, a plurality of first division patterns 800 may be spaced apart from each other in the third direction D3.

In example embodiments, each of the gate electrode structures divided by the first division pattern 800 and the first memory channel structures 750 extending through each of the gate electrode structures may collectively form a memory block, and a plurality of memory blocks may be arranged in the third direction D3.

The second division pattern 850 may be disposed between neighboring ones of the first division patterns 800 in the third direction D3, and may extend in the second direction D2 on the first and second regions I and II of the third substrate 300. The second division pattern 850 may extend through the second to fourth insulating interlayers 640, 760 and 810, the third gate electrodes 796, the third insulation pattern 475, upper portions of some of the first support structures 755, and upper portions of some of the first memory channel structures 750.

In example embodiments, a plurality of second division patterns 850 may be spaced apart from each other in the third direction D3. In an example embodiment, seven second division patterns 850 may be disposed between neighboring ones of the first division patterns 800 in the third direction D3, and thus eight third gate electrodes 796 may be disposed at a single level in each of the memory blocks. However, the inventive concept is not limited thereto, and for example, three second division patterns 850 may be disposed between neighboring ones of the first division patterns 800 in the third direction D3 and four third gate electrodes 796 may be disposed at a single level in each of the memory blocks.

Each of the first and second division patterns 800 and 850 may include an oxide, e.g., silicon oxide.

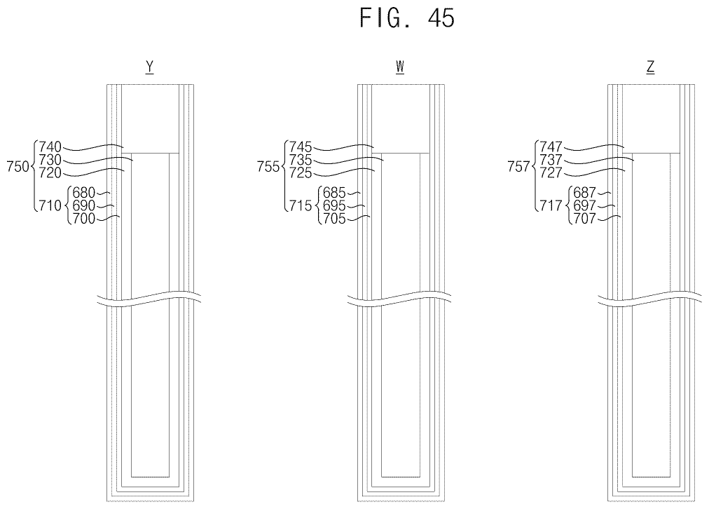

Referring to FIG. 45 together with FIGS. 19 to 25, the first memory channel structure 750 may be disposed on the first region I of the third substrate 300 to contact the upper surface of the CSP 400, and may extend through the channel connection pattern 780, the support layer 460, the gate electrode structure, the third insulation pattern 475, and the first and second insulating interlayers 530 and 640 in each of the memory blocks.

The first memory channel structure 750 may include a first filling pattern 730, which may extend in the first direction D1 and have a pillar shape, a first channel 720, which may cover a sidewall and a lower surface of the first filling pattern 730 and have a cup shape, a first capping pattern 740 contacting upper surfaces of the first channel 720 and the first filling pattern 730, and a first charge storage structure 710 on an outer sidewall and a lower surface of the first channel 720 and a sidewall of the first capping pattern 740. The first charge storage structure 710 may include a first tunnel insulation pattern 700, a first charge storage pattern 690 and a first blocking pattern 680 sequentially stacked in the horizontal direction from the outer sidewall of the first channel 720.

The first charge storage structure 710 may not entirely cover but may partially cover the outer sidewall of the first channel 720, and an exposed portion of the first channel 720 may contact the channel connection pattern 780 to be electrically connected thereto. Thus, a plurality of first channels 720 in each of the memory block may be electrically connected to each other through the channel connection pattern 780.

The second memory channel structure 755 may include a second filling pattern 735, which may extend in the first direction D1 and have a pillar shape, a second channel 725, which may cover a sidewall and a lower surface of the second filling pattern 735 and have a cup shape, a second capping pattern 745 contacting upper surfaces of the second channel 725 and the second filling pattern 735, and a second charge storage structure 715 on an outer sidewall and a lower surface of the second channel 725 and a sidewall of the second capping pattern 745. The second charge storage structure 715 may include a second tunnel insulation pattern 705, a second charge storage pattern 695 and a second blocking pattern 685 sequentially stacked in the horizontal direction from the outer sidewall of the second channel 725.

Further, the third memory channel structure 757 may include a third filling pattern 737, which may extend in the first direction D1 and have a pillar shape, a third channel 727, which may cover a sidewall and a lower surface of the third filling pattern 737 and have a cup shape, a third capping pattern 747 contacting upper surfaces of the third channel 727 and the third filling pattern 737, and a third charge storage structure 717 on an outer sidewall and a lower surface of the third channel 727 and a sidewall of the third capping pattern 747. The third charge storage structure 717 may include a third tunnel insulation pattern 707, a third charge storage pattern 697 and a third blocking pattern 687 sequentially stacked in the horizontal direction from the outer sidewall of the third channel 727.

Unlike the first memory channel structure 750 on the first region I of the third substrate 300, each of the second and third memory channel structures 755 and 757 on the second and third regions II and III may be a dummy memory channel structure not serving as an active memory or an active channel, and may support molds. Thus, the second and third memory channel structures 755 and 757 may also be referred to as first and second support structures 755 and 757.

A plurality of first memory channel structures 750 may be spaced apart from each other in the second and third directions D2 and D3 in each of the memory blocks on the first region I of the third substrate 300 to form a first memory channel structure array, and a plurality of second support structures 757 may be spaced apart from each other in the second and third directions D2 and D3 in each of the memory blocks on the third region III of the third substrate 300 to form a second support structure array.

In example embodiments, a plurality of first support structures 755 may be spaced apart from each other in the fourth direction D4 by a first distance on the second region II of the third substrate 300 to form a first support structure column, and a plurality of first support structure columns may be spaced apart from each other in the second direction D2 by a second distance to form a first support structure group. In an example embodiment, the first support structure group may include three first support structure columns spaced apart from each other in the second direction D2.

In example embodiments, a plurality of first support structure groups may be spaced apart from each other in each of the second and third directions D2 and D3 in each of the memory blocks to form a first support structure array.

In an example embodiment, two first support structure groups may be disposed between ones of the first division patterns 800 neighboring in the third direction D3. The first support structures 755 in the first support structure groups, respectively, may be arranged in the same layout in a plan view. Alternatively, the first support structures 755 in the first support structure groups, respectively, may be arranged in a symmetrical layout with reference to an imaginary straight line extending in the second direction D2 in a plan view.

In example embodiments, some of the first support structures 755 included in each of the first support structure groups may be arranged at vertices and a center of a regular hexagon in a plan view. That is, within each of the first support structure groups, the first distance between ones of the first support structures 755 spaced apart from each other in the fourth direction D4 may be substantially equal to the second distance between ones of the first support structures 755 spaced apart from each other in the second direction D2, and thus seven neighboring first support structures 755 in each of the first support structure groups may be arranged at six vertices and a center of a regular hexagon in a plan view.

As illustrated above, the first support structure array may include the first support structures 755 that are regularly arranged so as to efficiently support the molds when the semiconductor device is manufactured.

In example embodiments, the second division pattern 850 may extend through upper portions of some of the first support structures 755 disposed in the second direction D2 among the first support structures 755 included in each of the first support structure groups, and may contact upper surfaces of the second channel 725 and the second charge storage structure 715 included in a corresponding one of the first support structures 755.

FIG. 20 shows four first support structures spaced apart from each other in the second direction D2, however, the inventive concept is not limited thereto.

Each of the first to third channels 720, 725 and 727 may include, e.g., undoped polysilicon, each of the first to third filling patterns 730, 735 and 737 may include an oxide, e.g., silicon oxide, and each of the first to third capping patterns 740, 745 and 747 may include, e.g., polysilicon doped with impurities.

Each of the first to third tunnel insulation patterns 700, 705 and 707 may include an oxide, e.g., silicon oxide, each of the first to third charge storage patterns 690, 695 and 697 may include a nitride, e.g., silicon nitride, and each of the first to third blocking patterns 680, 685 and 687 may include an oxide, e.g., silicon oxide.

The fourth blocking pattern 785 may cover upper and lower surfaces of each of the first to third gate electrodes 792, 794 and 796 and a sidewall of each of the first to third gate electrodes 792, 794 and 796 that may face the first to third memory channel structures 750, 755 and 757, and the first to fifth upper contact plugs 862, 864, 866, 868 and 875, sidewalls of the third insulation patterns 475, and a portion of a sidewall of the first division pattern 800. The fourth blocking pattern 785 may contact sidewalls of the first to third memory channel structures 750, 755 and 757 and the first to fifth upper contact plugs 862, 864, 866, 868 and 875.

The fourth blocking pattern 785 may include a metal oxide, e.g., aluminum oxide, hafnium oxide, etc.

The first upper insulating interlayer 530 may be disposed between lower ones of the second gate electrodes 794 and upper ones of the second gate electrodes 794 in the gate electrode structure. The second upper insulating interlayer 640 may be disposed on ones of the third insulation patterns 475 on an uppermost one of the third gate electrodes 796 in the gate electrode structure, and may cover upper sidewalls of the first to third memory channel structures 750, 755 and 757.

The third and fourth insulating interlayers 760 and 810 may be sequentially stacked in the first direction D1 on the second upper insulating interlayer 640 and the first to third memory channel structures 750, 755 and 757, and may cover upper sidewalls of the first to fifth upper contact plugs 862, 864, 866, 868 and 875 and an upper sidewall of the second division pattern 850.

The fifth and sixth upper insulating interlayers 880 and 900 may be sequentially stacked in the first direction D1 on the fourth upper insulating interlayer 810, the first to fifth upper contact plugs 862, 864, 866, 868 and 875 and the second division pattern 850.

Each of the first to sixth upper insulating interlayers 530, 640, 760, 810, 880 and 900 may include an oxide, e.g., silicon oxide, or a low-k dielectric material, and some of the first to sixth upper insulating interlayers 530, 640, 760, 810, 880 and 900 may be merged with each other.

The first to fourth upper contact plugs 862, 864, 866 and 868 may be spaced apart from each other in the third direction D3 on the third region III of the third substrate 300. A plurality of first upper contact plugs 862 may be spaced apart from each other in the second direction D2, a plurality of second upper contact plugs 864 may be spaced apart from each other in the second direction D2, a plurality of third upper contact plugs 866 may be spaced apart from each other in the second direction D2, and a plurality of fourth upper contact plugs 868 may be spaced apart from each other in the second direction D2.

FIG. 20 shows the first to fourth upper contact plugs 862, 864, 866 and 868 are arranged in the third direction D3 in this order on the third region III of the third substrate 300, however, the inventive concept is not limited thereto.

FIG. 20 shows four upper contact plugs, that is, the first to fourth upper contact plugs 862, 864, 866 and 868 are disposed in the third direction D3 on the third region III of the third substrate 300, however, the inventive concept is not limited thereto, and for example, two or three upper contact plugs may be disposed in the third direction D3.

In example embodiments, each of the first and second upper contact plugs 862 and 864 may extend through the first to fourth insulating interlayers 530, 640, 760 and 810, a portion of the gate electrode structure, the third insulation pattern 475 and the fourth blocking pattern 785, and may contact a corresponding one of the first and second gate electrodes 792 and 794 included in the gate electrode structure to be electrically connected thereto.

Additionally, each of the third and fourth upper contact plugs 866 and 868 may extend through the second to fourth insulating interlayers 640, 760 and 810, a portion of the gate electrode structure, the third insulation pattern 475 and the fourth blocking pattern 785, and may contact a corresponding one of the second gate electrodes 794 included in the gate electrode structure to be electrically connected thereto.

That is, each of the first to fourth upper contact plugs 862, 864, 866 and 868 may contact an upper surface of a corresponding one of the first and second gate electrodes 792 and 794 included in the gate electrode structure, and may be electrically connected thereto. Each of the first to fourth upper contact plugs 862, 864, 866 and 868 may extend through other ones of the first and second gate electrodes 792 and 794 and the third gate electrodes 796 over the corresponding one of the first and second gate electrodes 792 and 794, but may be electrically insulated therefrom by the first spacer 510 or the second spacer 600.

In example embodiments, lower surfaces of the first upper contact plugs 862 may be lower than lower surfaces of the second upper contact plugs 864, the lower surfaces of the second upper contact plugs 864 may be lower than lower surfaces of the third upper contact plugs 866, and the lower surfaces of the third upper contact plugs 866 may be lower than lower surfaces of the fourth upper contact plugs 868.

Heights of ones of the first upper contact plugs 862 disposed in the second direction D2 may increase or decrease gradually or in a stepwise manner, heights of ones of the second upper contact plugs 864 disposed in the second direction D2 may increase or decrease gradually or in a stepwise manner, heights of ones of the third upper contact plugs 866 disposed in the second direction D2 may increase or decrease gradually or in a stepwise manner, and heights of ones of the fourth upper contact plugs 864 disposed in the second direction D2 may increase or decrease gradually or in a stepwise manner.

In example embodiments, a width in the horizontal direction of each of the first to fourth upper contact plugs 862, 864, 866 and 868 may not be constant in the first direction D1, and may decrease from a top toward a bottom thereof in a stepwise manner. Each of the first to fourth upper contact plugs 862, 864, 866 and 868 may include a plurality of portions stacked in the first direction D1 and having different widths in the horizontal direction.

In example embodiments, the first spacer 510 may be disposed on a sidewall of a lower portion of each of the first and second upper contact plugs 862 and 864, and the second spacer 600 may be disposed on a sidewall of an upper portion of each of the first and second upper contact plugs 862 and 864 and a sidewall of each of the third and fourth upper contact plugs 866 and 868. The first spacer 510 may not be disposed on a sidewall of a portion of each of the first and second upper contact plugs 862 and 864 extending through the first upper insulating interlayer 530, and the portion may contact the first upper insulating interlayer 530.

Each of the first and second spacers 510 and 600 may include an oxide, e.g., silicon oxide.

In example embodiments, two fifth upper contact plugs 875 may be disposed at opposite sides, respectively, in the third direction D3 of the second division pattern 850 on the second region II of the third substrate 300 to form a fifth upper contact plug pair, and a plurality of fifth upper contact plug pairs may be spaced apart from each other in the second direction D2 to form a fifth upper contact plug pair column. Additionally, a plurality of fifth upper contact plug pair columns may be spaced apart from each other in the third direction D3 to form a fifth upper contact plug pair array.

In example embodiments, the fifth upper contact plugs 875 included in the fifth upper contact plug pair column may be disposed at opposite sides, respectively, in the third direction D3 of odd-numbered ones of the second division patterns 850 among the second division patterns 850 between ones of the first division patterns 800 neighboring in the third direction D3.

In example embodiments, each of the fifth upper contact plugs 875 may have a shape of a portion of a circular ring or a donut in a plan view, and the fifth upper contact plugs 875 included in the fifth upper contact plug pair may be symmetrical with reference to the second division pattern 850. Each of opposite ends in the second direction D2 of each of the fifth upper contact plugs 875 may contact a sidewall in the third direction D3 of the second division pattern 850, and a central portion in the second direction D2 of each of the fifth upper contact plugs 875 may be spaced apart from a sidewall in the third direction D3 of the second division pattern 850.

In example embodiments, the fifth upper contact plug pairs may be arranged in a honeycomb (i.e., hexagonal) pattern in a plan view.

In example embodiments, the fifth upper contact plug 875 may extend through the second to fourth upper insulating interlayers 640, 760 and 810, the third insulation patterns 475 and ones of the third gate electrodes 796, and may contact an upper surface of a corresponding one of the third gate electrodes 796 to be electrically connected thereto. The fifth upper contact plug 875 may be electrically insulated from other ones of the third gate electrodes 796 over the corresponding one of the third gate electrodes 796 by the second spacer 600 on sidewalls of the other ones of the third gate electrodes 796.

In example embodiments, a width in the horizontal direction of each of the fifth upper contact plugs 875 may not be constant in the first direction D1, and may decrease from a top toward a bottom thereof in a stepwise manner.

In example embodiments, heights of lower surfaces of ones of the fifth upper contact plugs 875 disposed in the second direction D2 included in each of the fifth upper contact plug columns may sequentially increase or decrease in the second direction D2. FIG. 20 shows each of the fifth upper contact plug columns includes four fifth upper contact plugs 875 disposed in the second direction D2, however, the inventive concept is not limited thereto, and may include more or less than four fifth upper contact plugs 875.

In example embodiments, a lower surface of each of the fifth upper contact plugs 875 may be higher than a lower surface of the second division pattern 850. Thus, only one fifth upper contact plug 875 may contact each of the third gate electrodes 796 separated from other third gate electrodes 796 by the second division pattern 850 at a single level to be electrically connected thereto.

The first upper via 890 may extend through the fifth upper insulating interlayer 880 to contact an upper surface of each of the first to fourth upper contact plugs 862, 864, 866 and 868, the second upper via 895 may extend through the fifth upper insulating interlayer 880 to contact an upper surface of the fifth upper contact plug 875, and the third upper via 897 may extend through the third to fifth upper insulating interlayers 760, 810 and 880 to contact an upper surface of the first capping pattern 740 included in the first memory channel structure 750. The third upper via 897 may also extend through a portion of the second division pattern 850.

Each of the first to third upper wirings 910, 915 and 917 may extend through the sixth upper insulating interlayer 900 to contact upper surfaces of the first to third upper vias 890, 895 and 897, respectively.

In example embodiments, the third upper wiring 917 may extend in the third direction D3 on the first region I of the third substrate 300, and a plurality of third upper wirings 917 may be spaced apart from each other in the second direction D2. Each of the first upper wirings 917 may serve as a bit line.

FIGS. 20 to 25 show the first to third upper wirings 910, 915 and 917 as upper wirings and the first to third upper vias 890, 895 and 897 as upper vias, however, the inventive concept is not limited thereto, and the semiconductor device may include additional upper wirings and/or additional upper vias.

Each of the first to fifth upper contact plugs 862, 864, 866, 868 and 875, the first to third upper vias 890, 895 and 897, and the first to third upper wirings 910, 915 and 917 may include a conductive material, e.g., a metal, a metal nitride, a metal silicide, etc.

The semiconductor device may have the gate electrode structure including the first to third gate electrodes 792, 794 and 796 stacked in the first direction D1, the first upper contact plugs 862 may contact upper surfaces of the first gate electrodes 792, respectively, the first to fourth upper contact plugs 864, 866 and 868 may contact upper surfaces of the second gate electrodes 794, respectively, and the fifth upper contact plugs 875 may contact upper surfaces of the third gate electrodes 796, respectively.

Each of the first to third gate electrodes 792, 794 and 796 may extend in the second direction D2, and may have a constant thickness in the second direction D2. Lengths in the second direction D2 of the first to third gate electrodes 792, 794 and 796 may be substantially the same as each other. Thus, the gate electrode structure may not have a staircase shape, and processes for forming the gate electrode structure may be simplified.

Each of the first to fifth upper contact plugs 862, 864, 866, 868 and 875 for transferring electrical signals to the first to third gate electrodes 792, 794 and 796 included in the gate electrode structure not having the staircase shape may contact an upper surface of only one of the first to third gate electrodes 792, 794 and 796, but may extend through other ones of the first to third gate electrodes 792, 794 and 796 thereover. The first spacer 510 or the second spacer 600 may be disposed between each of the first to fifth upper contact plugs 862, 864, 866, 868 and 875 and the other ones of the first to third gate electrodes 792, 794 and 796 so that each of the first to fifth upper contact plugs 862, 864, 866, 868 and 875 may be electrically insulated from the other ones of the first to third gate electrodes 792, 794 and 796.

Unlike the first and second gate electrodes 792 and 794, the third gate electrode 796, which may be disposed over the first and second gate electrodes 792 and 794, may be divided into a plurality of portions, e.g., eight portions by the second division patterns 850, and thus an area of each of the third gate electrodes 796 may be smaller than an area of each of the first and second gate electrodes 792 and 794.

If the fifth upper contact plugs 875 contacting the upper surfaces of the third gate electrodes 796, respectively, are formed by the same processes for forming the first to fourth upper contact plugs 862, 864, 866 and 868 contacting the upper surfaces of the first and second gate electrodes 792 and 794 to have the same shape and layout, distances between the fifth upper contact plugs 875 are small so that the processes for forming the fifth upper contact plugs 875 may be difficult.

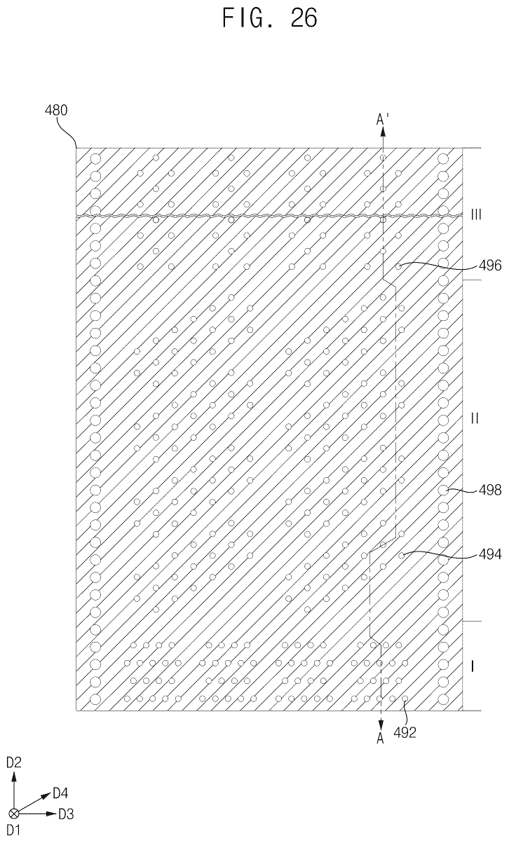

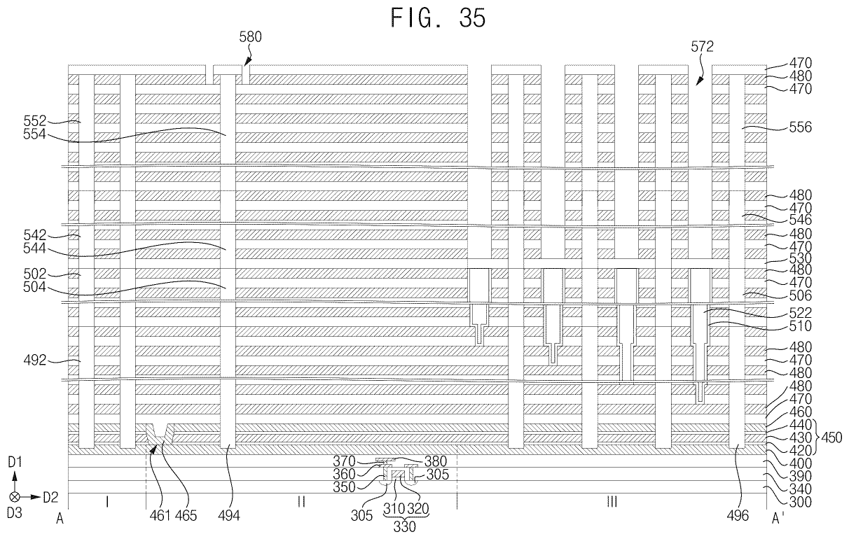

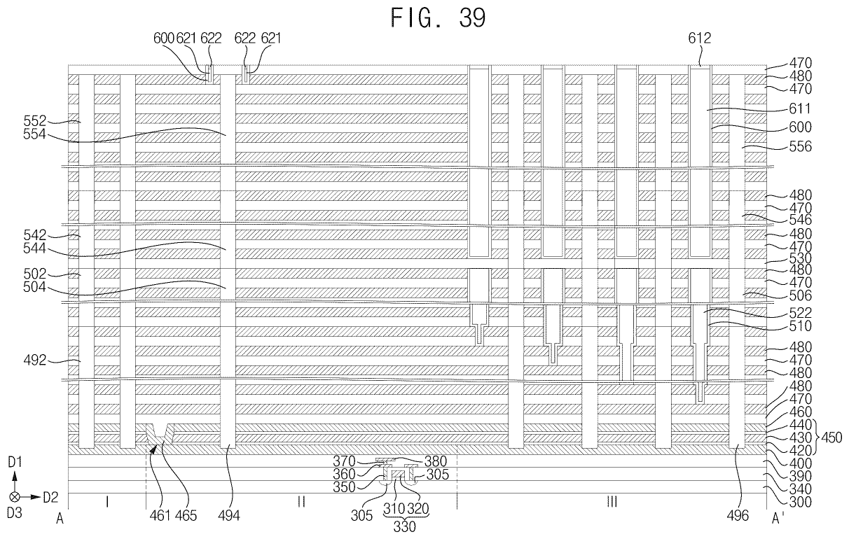

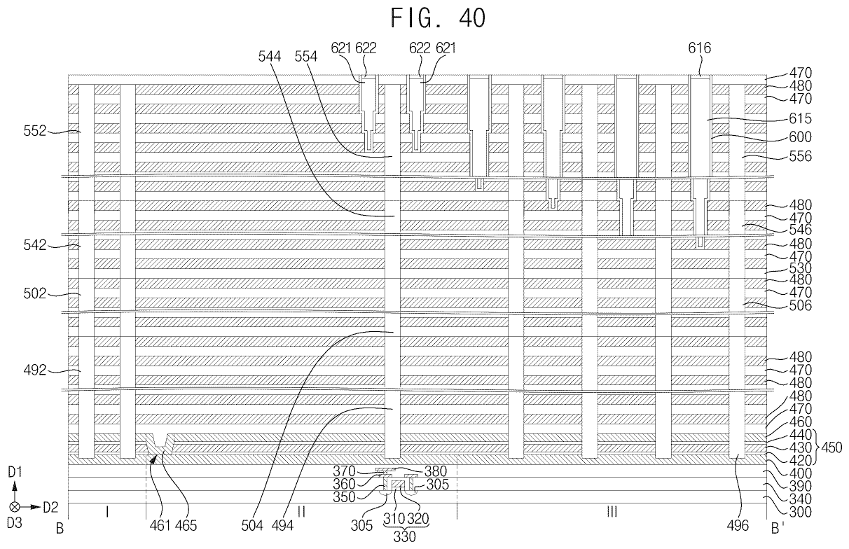

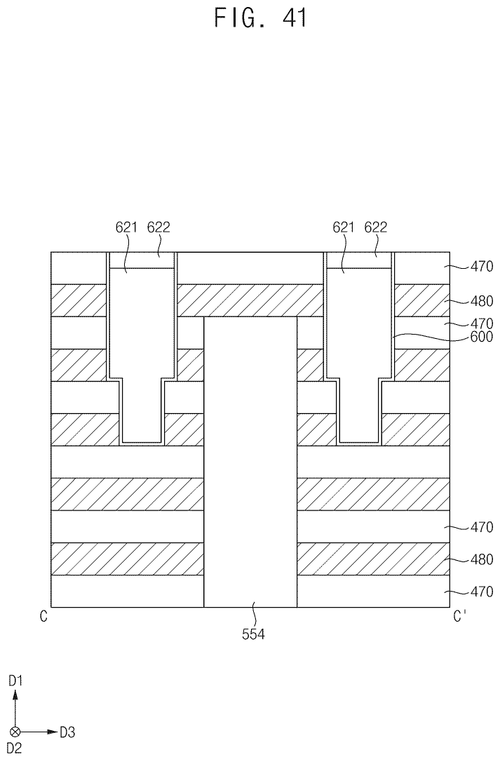

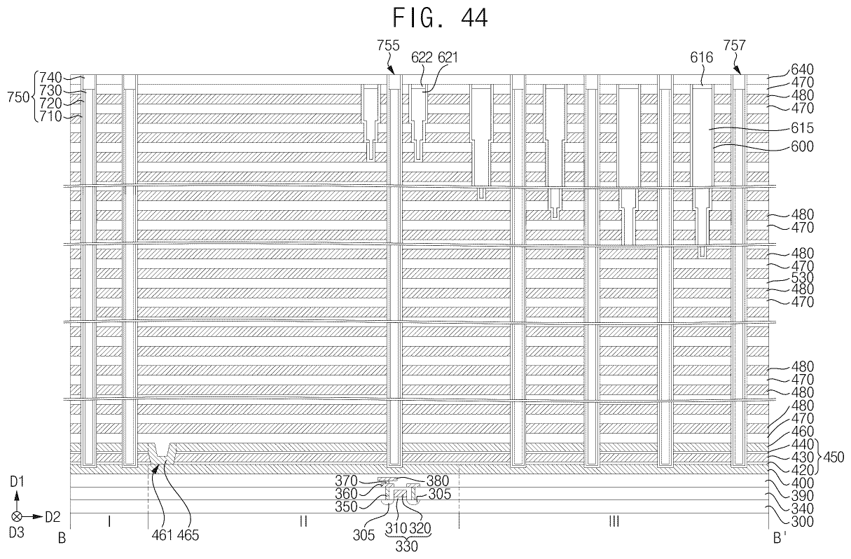

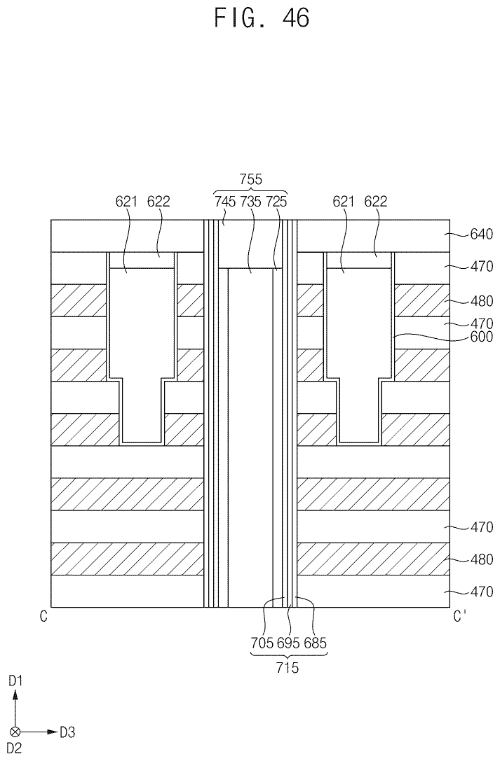

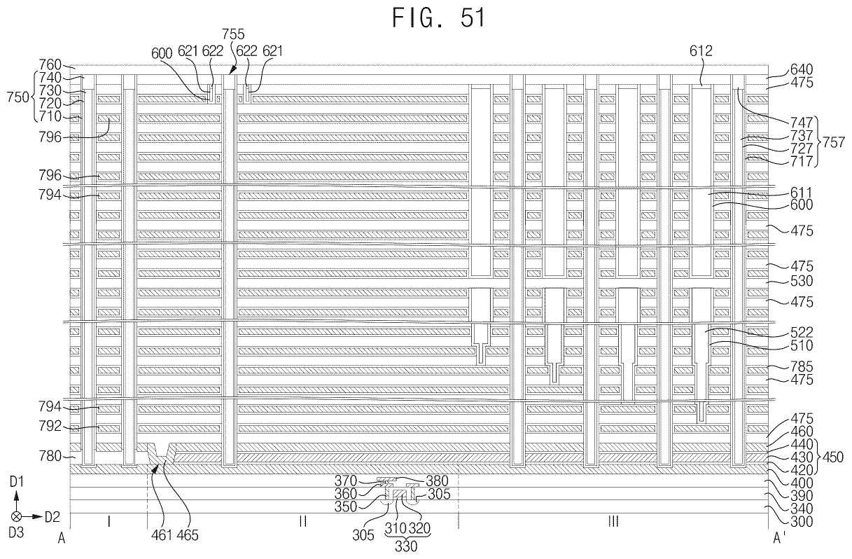

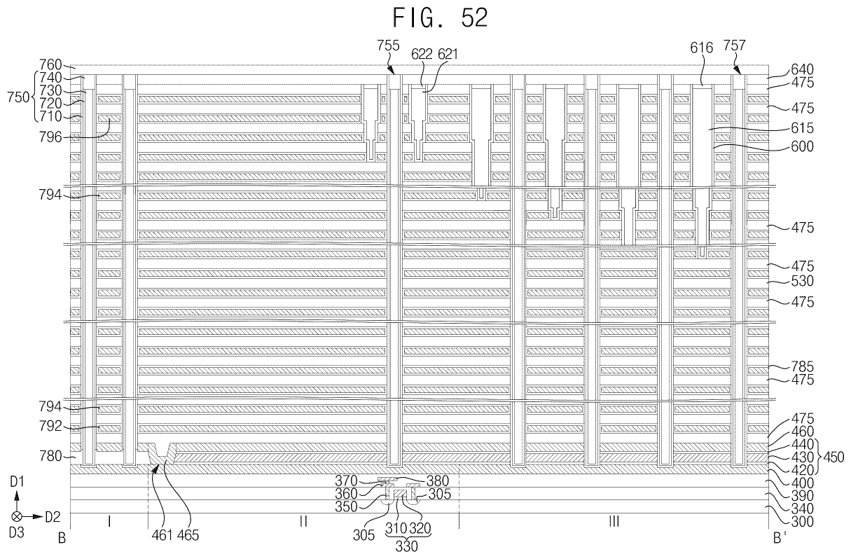

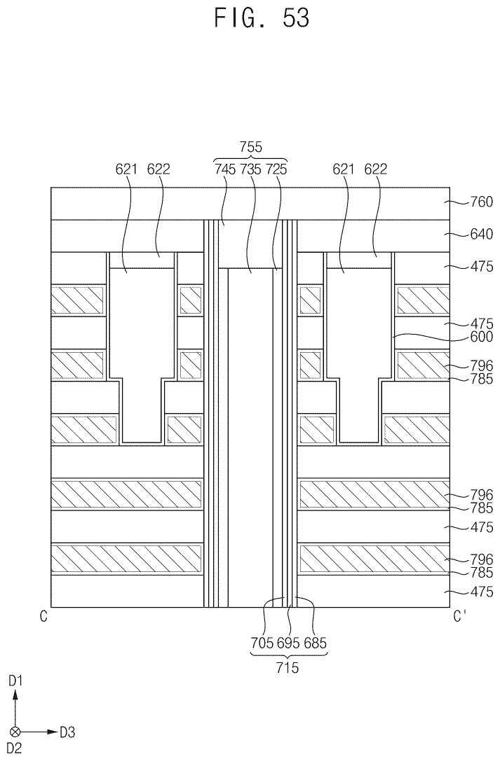

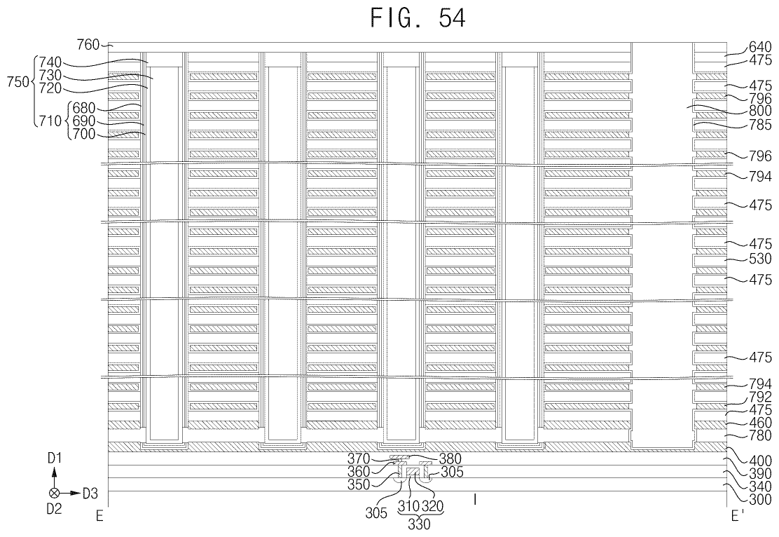

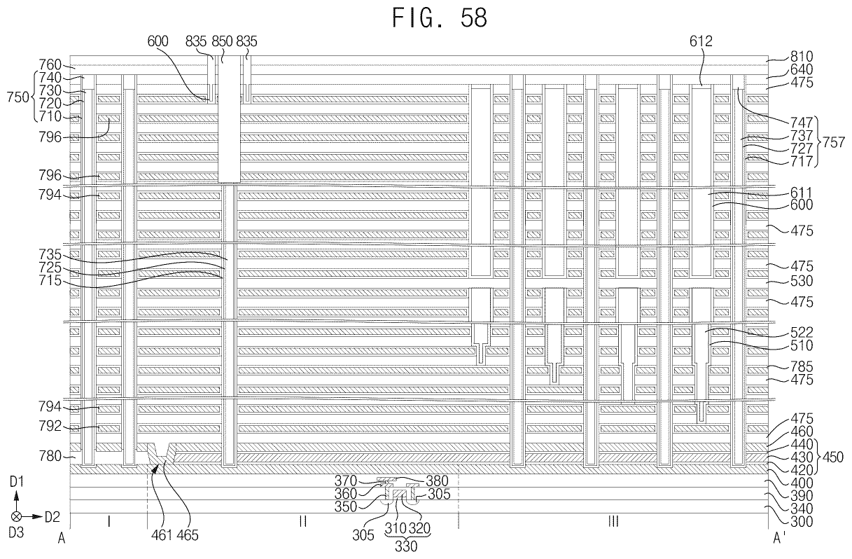

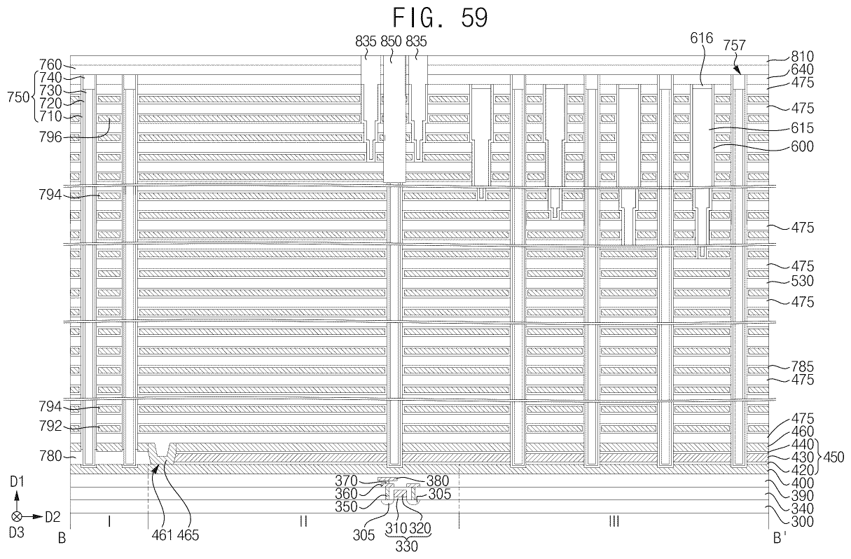

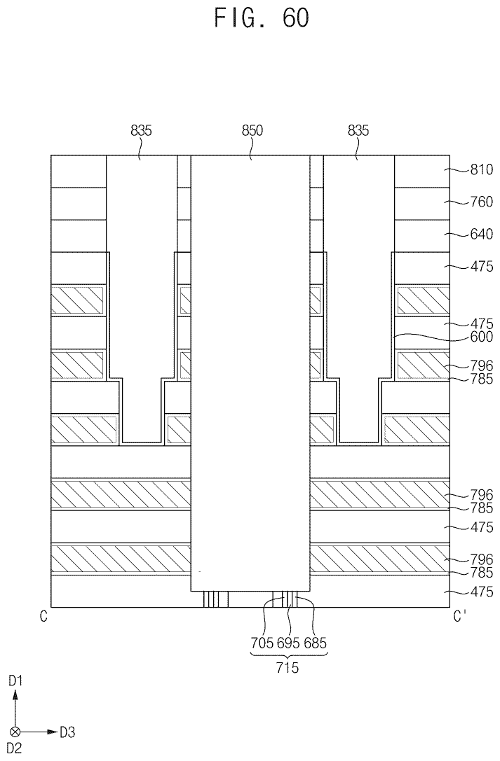

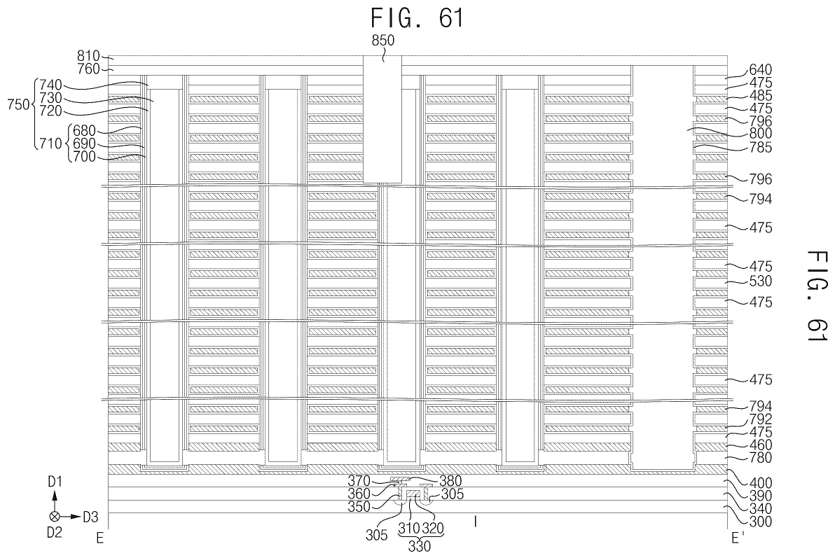

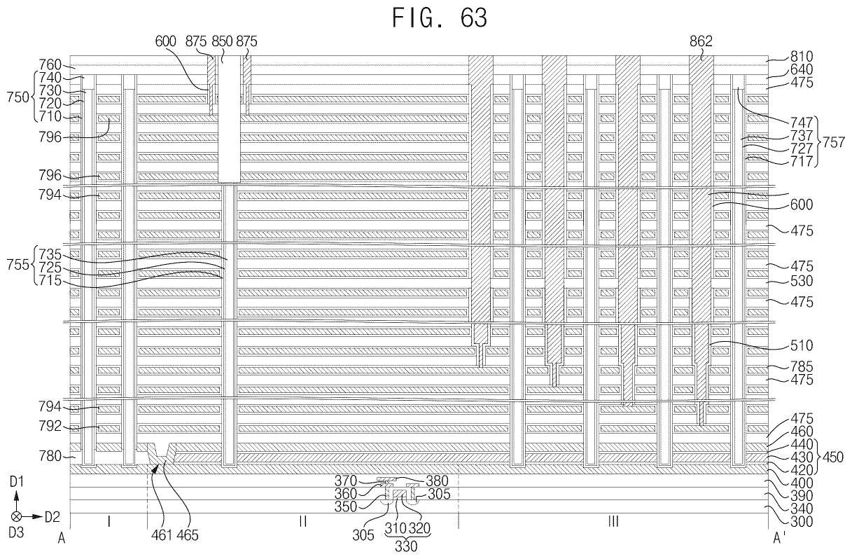

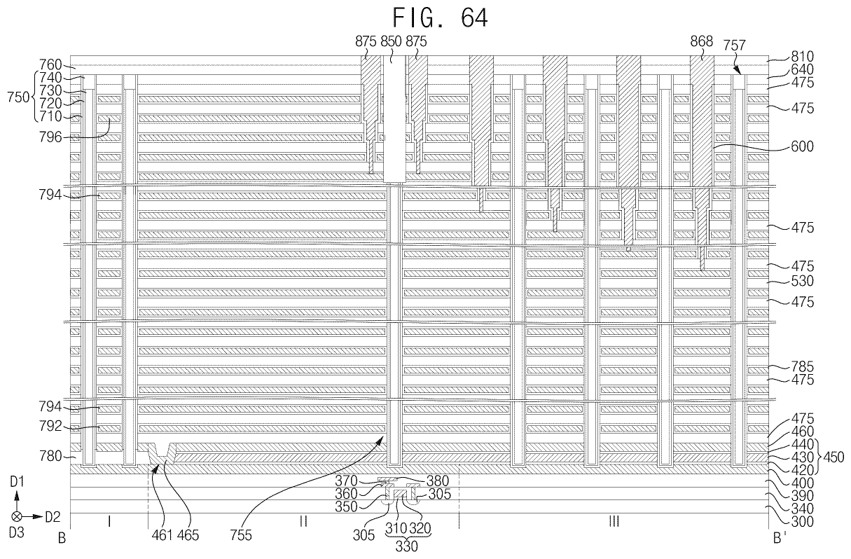

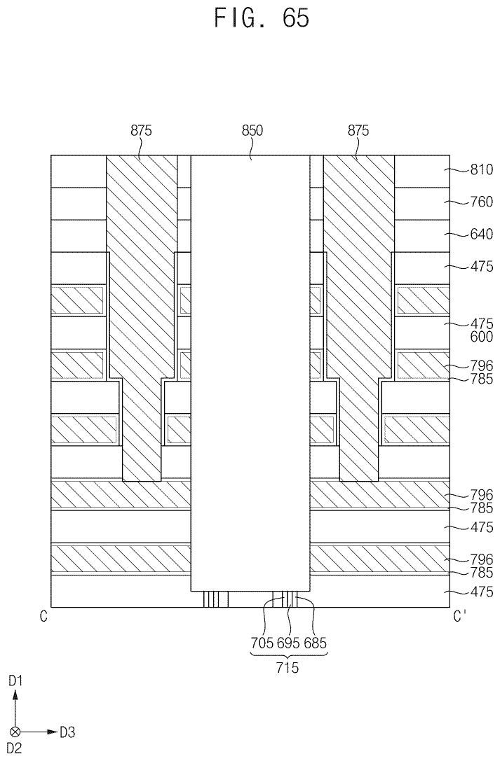

However, as illustrated below with reference to FIGS. 26 to 65, in example embodiments, the fifth upper contact plug 875 may be formed by forming a structure having a ring shape and dividing the ring shape into two parts through the second division pattern 850, so that the fifth upper contact plug 875 contacting the third gate electrode 796 having a relatively small area may be easily formed.

Additionally, the first support structures 755 surrounding the fifth upper contact plug 875 may be disposed at the vertices and the center of a regular hexagon, and thus may be arranged in a layout of a regular pattern so that the molds during manufacturing the semiconductor device may be efficiently prevented from collapsing. Accordingly, the semiconductor device may have enhanced structural stability.

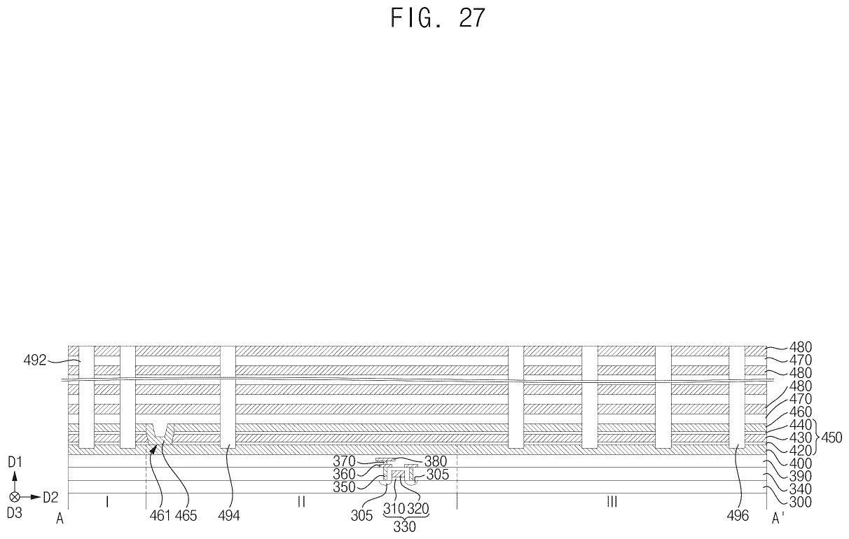

FIGS. 26 to 65 are plan views and cross-sectional views illustrating a method of manufacturing a semiconductor device. Particularly, FIGS. 26, 28, 30, 32, 34, 38, 42, 47, 50, 55, 57 and 62 are the plan views, and FIGS. 27, 29, 31, 33, 35-37, 39-41, 43-46, 48-49, 51-54, 56, 58-61 and 63-65 are the cross-sectional views.

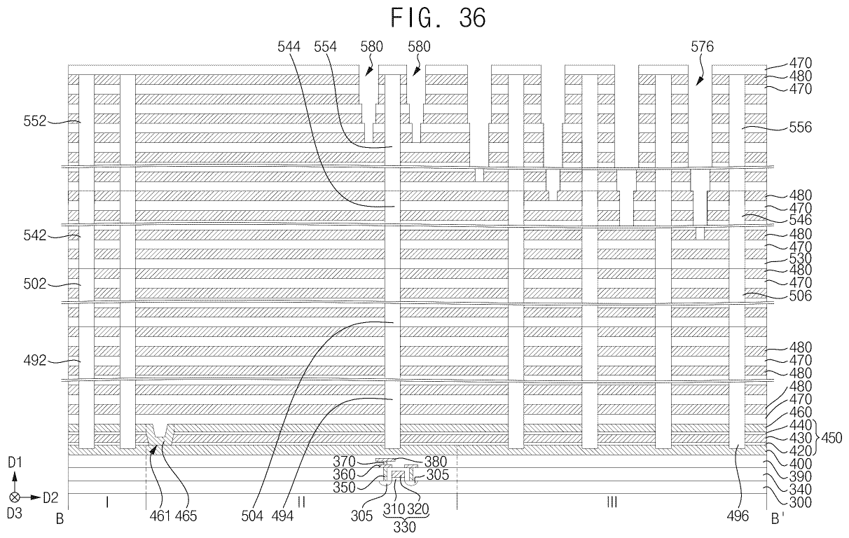

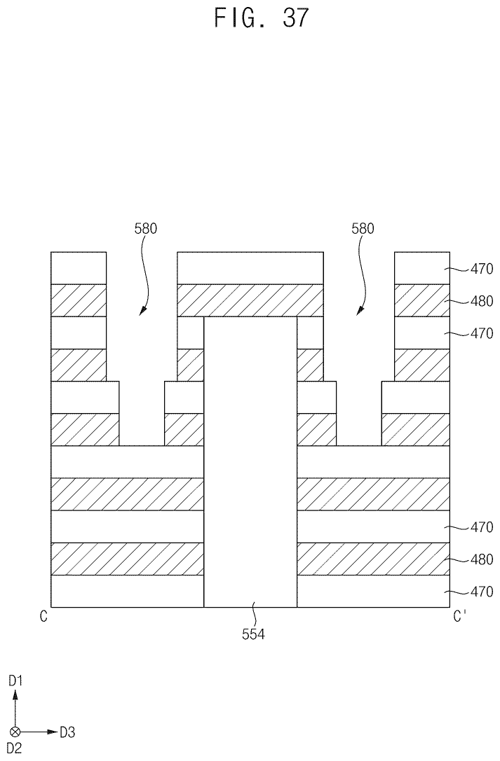

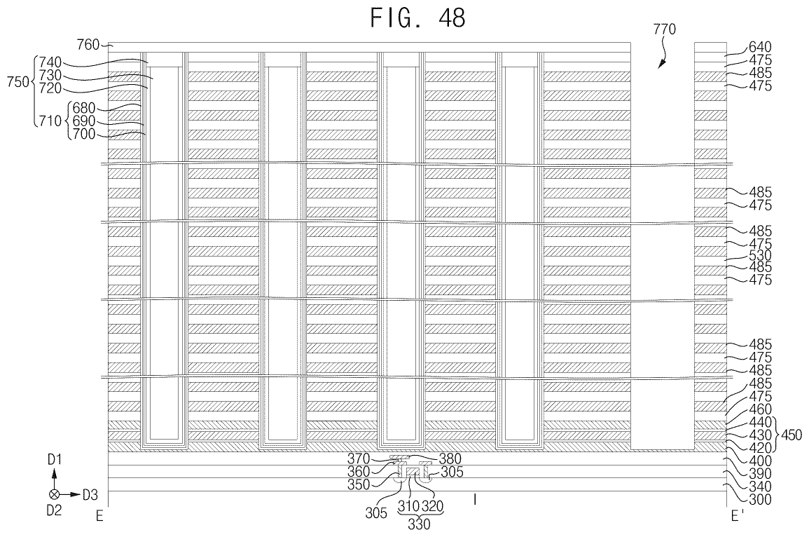

FIGS. 27, 29, 31, 33, 35, 39, 43, 51, 58 and 63 are cross-sectional views taken along lines A-A′ of corresponding plan views, respectively, FIGS. 36, 40, 44, 52, 59 and 64 are cross-sectional views taken along lines B-B′ of corresponding plan views, FIGS. 37, 41, 46, 53, 56, 60 and 65 are cross-sectional views taken along lines C-C′ of corresponding plan views, respectively, FIGS. 48, 49, 54 and 61 are cross-sectional views taken along lines E-E′ of corresponding plan views.

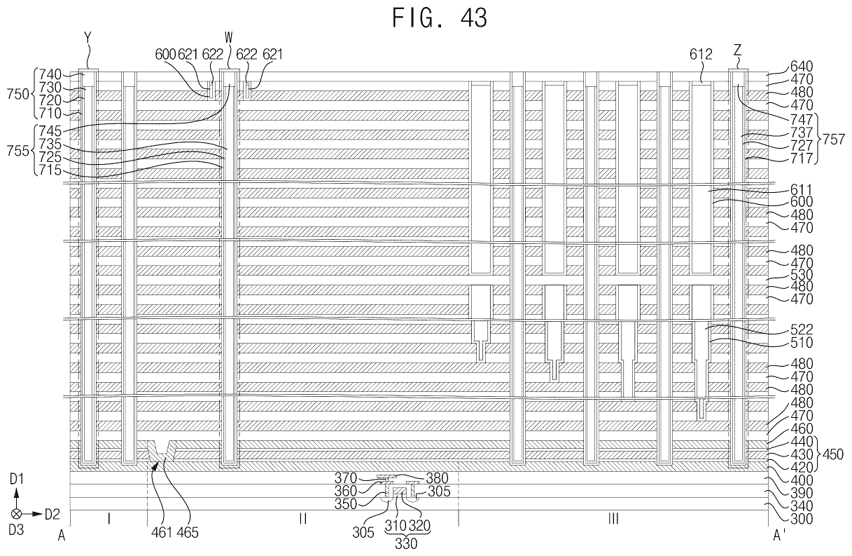

FIGS. 26 to 65 are drawings of region X of FIG. 19, and FIG. 45 includes enlarged cross-sectional views of regions Y, Z and W of FIG. 43.

Referring to FIGS. 26 and 27, a lower circuit pattern may be formed on a third substrate 300 including first to third regions I, II and III, and first and second lower insulating interlayers 340 and 390 may be sequentially stacked on the third substrate 300 to cover the lower circuit pattern.

Each element of the lower circuit pattern may be formed by a patterning process or a damascene process.

A CSP 400 and a sacrificial layer structure 450 may be sequentially formed on the second lower insulating interlayer 390, the sacrificial layer structure 450 may be partially removed to form a first opening 461 exposing an upper surface of the CSP 400, and a support layer 460 may be formed on an upper surface of the sacrificial layer structure 450 and the exposed upper surface of the CSP 400.

The sacrificial layer structure 450 may include third to fifth sacrificial layers 420, 430 and 440 sequentially stacked. Each of the third and fifth sacrificial layers 420 and 440 may include an oxide, e.g., silicon oxide, and the fourth sacrificial layer 430 may include a nitride, e.g., silicon nitride.

The support layer 460 may include a material having an etching selectivity with respect to the third to fifth sacrificial layers 420, 430 and 440, e.g., polysilicon doped with n-type impurities. The support layer 460 may be conformally formed, and thus a first recess may be formed on a portion of the support layer 460 in the first opening 461. Hereinafter, the portion of the support layer 460 in the first opening 461 which may contact the upper surface of the CSP 400 may be referred to as a support pattern 465.

The support pattern 465 may have various layouts in a plan view. In example embodiments, a plurality of support patterns 465 may be spaced apart from each other in each of the second and third directions D2 and D3 on the first region I of the third substrate 300, the support pattern 465 may extend in the third direction D3 on a portion of the second region II adjacent to the first region I of the third substrate 300, and a plurality of support patterns 465, each of which may extend in the second direction D2, may be spaced apart from each other in the third direction D3 on the second and third regions II and III of the third substrate 300. FIG. 27 shows the support pattern 465 extending in the third direction D3 on the portion of the second region II adjacent to the first region I of the third substrate 300.

A third insulation layer 470 and a sixth sacrificial layer 480 may be alternately and repeatedly stacked in the first direction D1 on the support layer 460 and the support pattern 465, and thus a third mold layer including the third insulation layers 470 and the sixth sacrificial layers 480 may be formed.

The third insulation layer 470 may include an oxide, e.g., silicon oxide, and the sixth sacrificial layer 480 may include a material having an etching selectivity with respect to the third insulation layer 470, e.g., a nitride such as silicon nitride.

First to fourth holes may be formed through the third mold layer, the support layer 460 and the sacrificial layer structure 450 to expose an upper surface of the CSP 400, and first to fourth sacrificial pillars 492, 494, 496 and 498 may be formed in the first to fourth holes, respectively.

In example embodiments, a plurality of first sacrificial pillars 492 may be formed on the first region I of the third substrate 300 to be spaced apart from each other in the second and third directions D2 and D3. A plurality of second sacrificial pillars 494 may be formed on the second region II of the third substrate 300 to be spaced apart from each other in the second and third directions D2 and D3. Further, a plurality of third sacrificial pillars 496 may be formed on the third region III of the third substrate 300 to be spaced apart from each other in the second and third directions D2 and D3.

A plurality of fourth sacrificial pillars 498 may be formed on the first to third regions I, II and III of the third substrate 300 to be spaced apart from each other in the second and third directions D2 and D3. In example embodiments, a plurality of fourth sacrificial pillars 498 disposed in the second direction D2 may form a fourth sacrificial pillar column, and a plurality of fourth sacrificial pillar columns may be spaced apart from each other in the third direction D3.

In example embodiments, a plurality of second sacrificial pillars 494 spaced apart from each other in the fourth direction D4 by a first distance to form a second sacrificial pillar column, and a plurality of second sacrificial pillar columns may be spaced apart from each other in the second direction D2.

In example embodiments, three second sacrificial pillar columns spaced apart from each other in the second direction D2 may form a second sacrificial pillar group, and a plurality of second sacrificial pillar groups may be spaced apart from each other in the third direction D3 between ones of the fourth sacrificial pillar columns neighboring in the third direction D3. A plurality of second sacrificial pillar groups may be spaced apart from each other in the second direction D2.

In an example embodiment, two second sacrificial pillar groups may be disposed between ones of the fourth sacrificial pillar columns neighboring in the third direction D3. The second sacrificial pillars 494 included in the second sacrificial pillar groups, respectively, may be arranged in the same layout in a plan view. Alternatively, second sacrificial pillars 494 included in the second sacrificial pillar groups, respectively, may be arranged in a symmetrical layout with reference to an imaginary straight line extending in the second direction D2 in a plan view.

In example embodiments, some of the second sacrificial pillars 494 included in each of the second sacrificial pillar groups may be arranged at vertices and a center of a regular hexagon in a plan view. That is, within each of the second sacrificial pillar groups, the first distance between ones of the second sacrificial pillars 494 spaced apart from each other in the fourth direction D4 may be substantially equal to the second distance between ones of the second sacrificial pillars 494 spaced apart from each other in the second direction D2, and thus seven neighboring second sacrificial pillars 494 in each of the second sacrificial pillar groups may be arranged at six vertices and a center of a regular hexagon in a plan view.

FIG. 26 shows fourth second sacrificial pillar groups spaced apart from each other in the second direction D2, however, the inventive concept is not limited thereto, and more or less than four second sacrificial pillar groups may be formed.

Each of the first to fourth sacrificial pillars 492, 494, 496 and 498 may include, e.g., a material containing carbon.

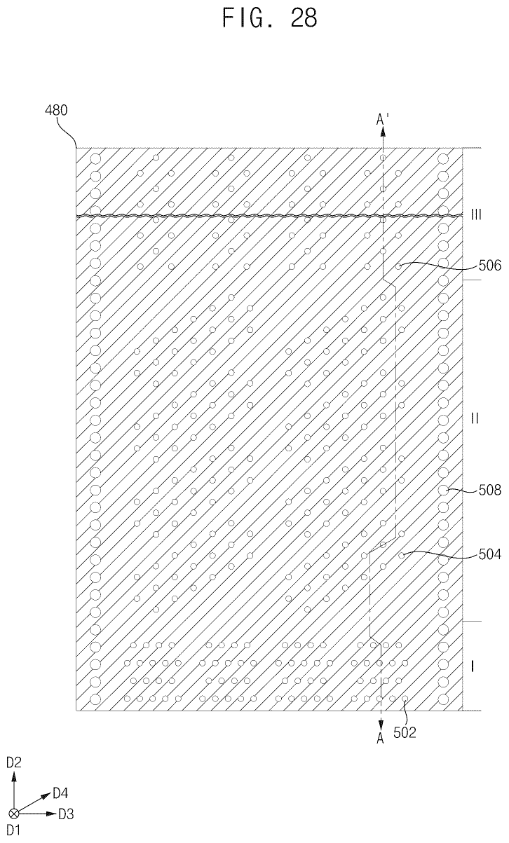

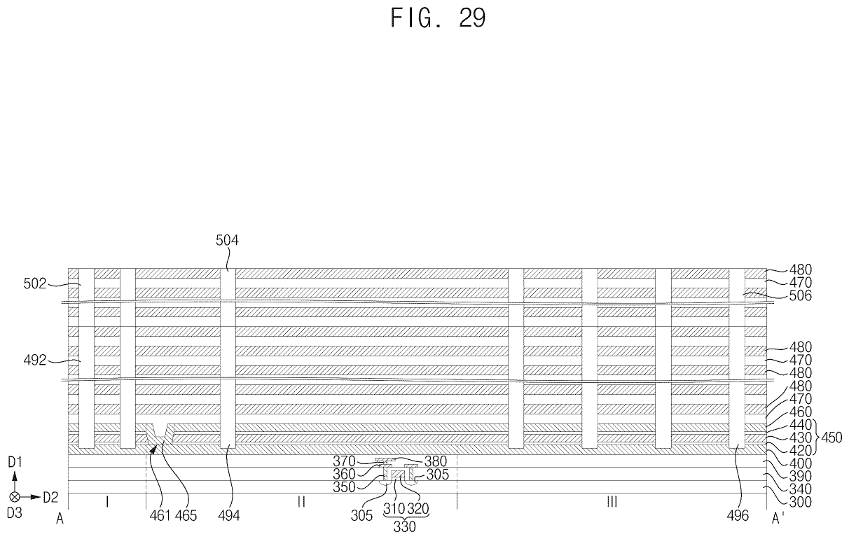

Referring to FIGS. 28 and 29, the third insulation layer 470 and the sixth sacrificial layer 480 may be alternately and repeatedly stacked again in the first direction D1 on the third mold layer, and thus a fourth mold layer including the third insulation layers 470 and the sixth sacrificial layers 480 may be formed.

Fifth to eighth holes may be formed through the fourth mold layer to expose upper surfaces of the first to fourth sacrificial pillars 492, 494, 496 and 498, respectively, and fifth to eighth sacrificial pillars 502, 504, 506 and 508 may be formed in the fifth to eighth holes, respectively.

Thus, the fifth to eighth sacrificial pillars 502, 504, 506 and 508 may contact upper surfaces of the first to fourth sacrificial pillars 492, 494, 496 and 498, respectively, and thus may have the same layout. Each of the fifth to eighth sacrificial pillars 502, 504, 506 and 508 may include a material substantially the same as that of the first to fourth sacrificial pillars 492, 494, 496 and 498, e.g., a material containing carbon.

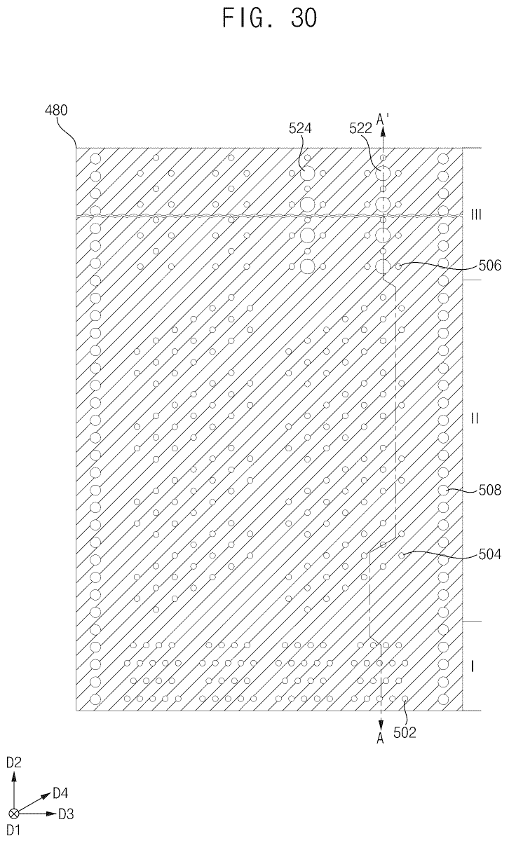

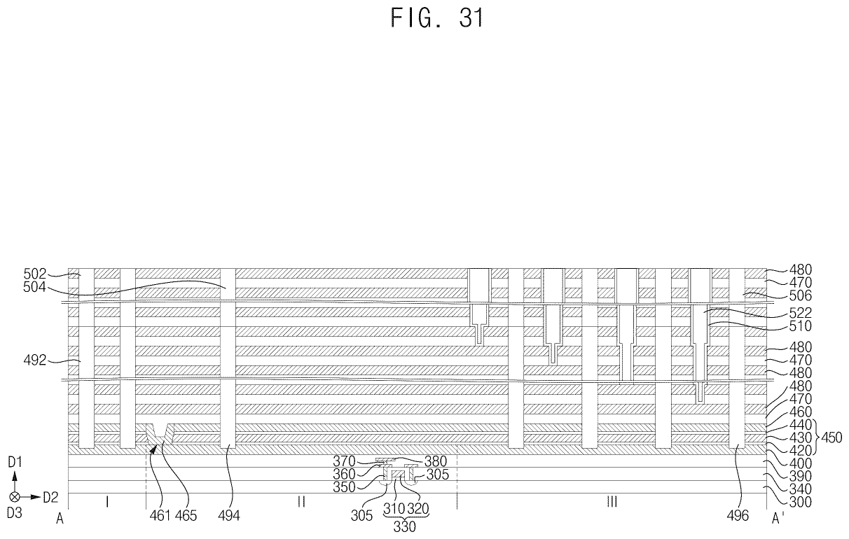

Referring to FIGS. 30 and 31, a third insulation layer 470 may be formed on the fourth mold layer and the fifth to eighth sacrificial pillars 502, 504, 506 and 508, and processes substantially the same as or similar to those illustrated with respect to FIGS. 1 to 10 may be performed to form a plurality of lower contact holes exposing upper surfaces of portions of a plurality of sixth sacrificial layers 480 at different levels in the third and fourth mold layers.

A first spacer layer may be formed on the exposed upper surfaces of the portions of the sixth sacrificial layers 480, inner walls of the lower contact holes, an upper surface of the fourth mold layer and upper surfaces of the fifth to eighth sacrificial pillars 502, 504, 506 and 508, a seventh sacrificial layer may be formed on the first spacer layer to fill the lower contact holes, and a planarization process may be performed on the seventh sacrificial layer and the first spacer layer until the upper surface of the fourth mold layer and the upper surfaces of the fifth to eighth sacrificial pillars 502, 504, 506 and 508 are exposed to form first and second sacrificial structures 522 and 524 and first spacers 510 covering lower surfaces and sidewalls of the first and second sacrificial structures 522 and 524 and contacting upper surfaces of the sixth sacrificial layers 480 in the lower contact holes.

In example embodiments, a plurality of first sacrificial structures 522 may be spaced apart from each other in the second direction D2 on the third region III of the third substrate 300, and a plurality of second sacrificial structures 524 may be spaced apart from each other in the second direction D2 on the third region III of the third substrate 300. The first sacrificial structures 522 and the second sacrificial structures 524 may be spaced apart from each other in the third direction D3. Each of the first and second sacrificial structures 522 and 524 may be formed on portions of the third and fourth mold layers surrounded by structures including the third and seventh sacrificial pillars 496 and 506.

In an example embodiment, lower surfaces of the first sacrificial structures 522 may be lower than lower surfaces of the second sacrificial structures 524. Alternatively, the lower surfaces of the first sacrificial structures 522 may be higher than the lower surfaces of the second sacrificial structures 524.

FIG. 31 shows that the lower surfaces of the first sacrificial structures 522 become lower as the first sacrificial structures 522 move away from the second region II of the third substrate 300, however, the inventive concept is not limited thereto, and on the contrary, the lower surfaces of the first sacrificial structures 522 may become higher as the first sacrificial structures 522 move away from the second region II of the third substrate 300.

Likewise, the lower surfaces of the second sacrificial structures 524 may also become lower or higher as the second sacrificial structures 524 move away from the second region II of the third substrate 300.

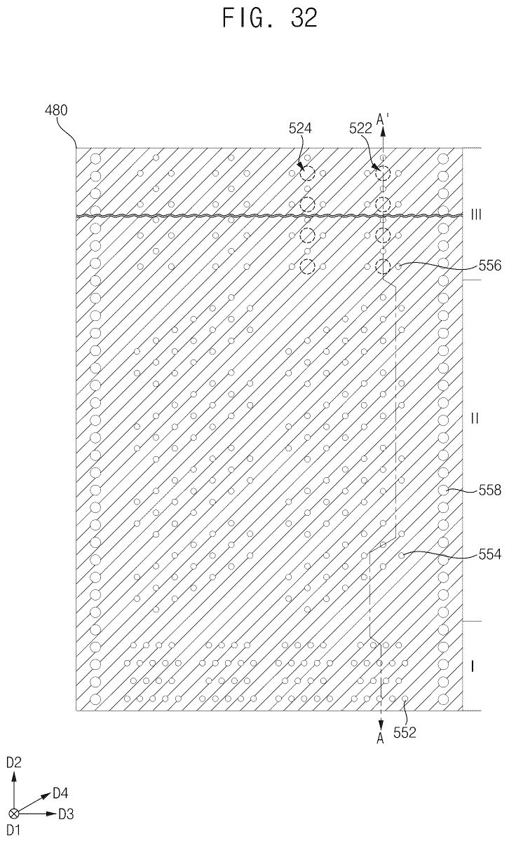

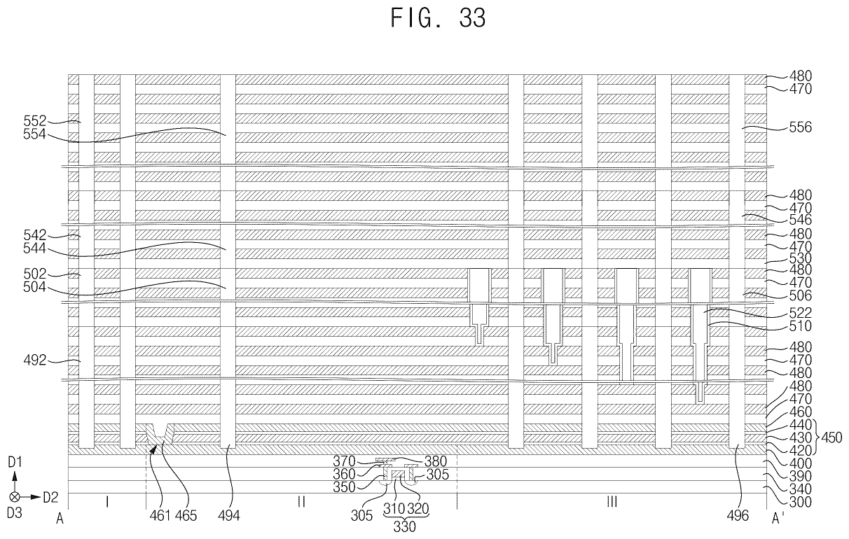

Referring to FIGS. 32 and 33, a first upper insulating interlayer 530 may be formed on the fourth mold layer, the fifth to eighth sacrificial pillars 502, 504, 506 and 508 and the first and second sacrificial pillars 522 and 524, and processes substantially the same as or similar to those illustrated with respect to FIGS. 26 to 29 may be performed so that fifth and sixth mold layers may be sequentially stacked on the first upper insulating interlayer 530.

In example embodiments, a ninth sacrificial pillar 542, a tenth sacrificial pillar 544, an eleventh sacrificial pillar 546 and a twelfth sacrificial pillar each of which may extend in the first direction D1 may be formed through the first upper insulating interlayer 530 and the fifth mold layer, and a thirteenth sacrificial pillar 552, a fourteenth sacrificial pillar 554, a fifteenth sacrificial pillar 556 and a sixteenth sacrificial pillar 558 each of which may extend in the first direction D1 may be formed through the sixth mold layer.

The ninth and thirteenth sacrificial pillars 542 and 552 may be sequentially stacked in the first direction D1 on the fifth sacrificial pillar 502, the tenth and fourteenth sacrificial pillars 544 and 554 may be sequentially stacked in the first direction D1 on the sixth sacrificial pillar 504, the eleventh and fifteenth sacrificial pillars 546 and 556 may be sequentially stacked in the first direction D1 on the seventh sacrificial pillar 506, and the twelfth sacrificial pillar and sixteenth sacrificial pillar 558 may be sequentially stacked in the first direction D1 on the eighth sacrificial pillar 508.

The ninth to eleventh sacrificial pillars 542, 544 and 546 and the twelfth sacrificial pillar may be arranged in the same layout as the fifth to eighth sacrificial pillars 502, 504, 506 and 508, and the thirteenth to sixteenth sacrificial pillars 552, 554, 556 and 558 may be arranged in the same layout as the ninth to eleventh sacrificial pillars 542, 544 and 546 and the twelfth sacrificial pillar.

As a result, the first, fifth, ninth and thirteenth sacrificial pillars 492, 502, 542 and 552 may be arranged in the same layout to form a first sacrificial pillar structure, the second, sixth, eighth and fourteenth sacrificial pillars 494, 504, 544 and 554 may be arranged in the same layout to form a second sacrificial pillar structure, the third, seventh, eleventh and fifteenth sacrificial pillars 496, 506, 546 and 556 may be arranged in the same layout to form a third sacrificial pillar structure, and the fourth and eighth sacrificial pillars 498 and 508, the twelfth sacrificial pillar and the sixteenth sacrificial pillar 558 may be arranged in the same layout to form a fourth sacrificial pillar structure. The first to fourth sacrificial pillar structures may have the same layout as the first to fourth sacrificial pillars 492, 494, 496 and 498, respectively.

Each of the ninth to eleventh sacrificial pillars 542, 544 and 546, the twelfth sacrificial pillar, and the thirteenth to sixteenth sacrificial pillars 552, 554, 556 and 558 may include a material substantially the same as that of each of the first to eighth sacrificial pillars 492, 494, 496, 498, 502, 504, 506 and 508, e.g., a material containing carbon.

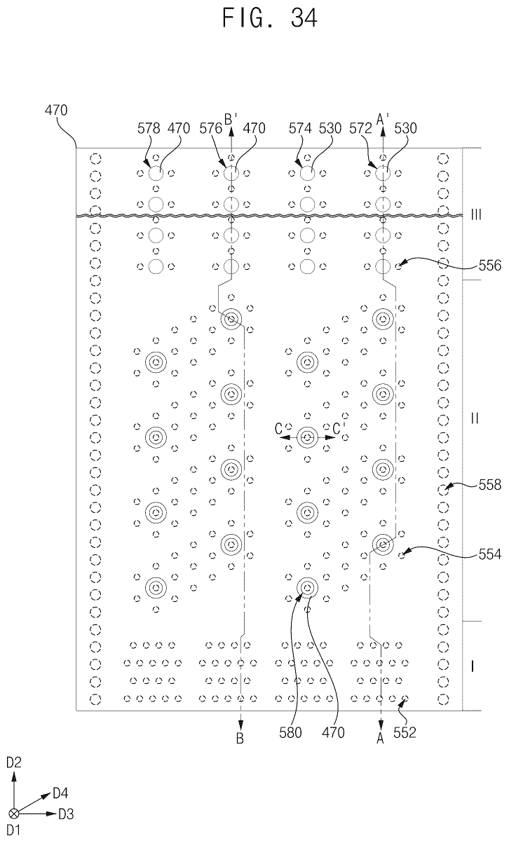

Referring to FIGS. 34 to 37, a third insulation layer 470 may be formed on the sixth mold layer and the thirteenth to sixteenth sacrificial pillars 552, 554, 556 and 558, and first and second upper contact holes 572 and 574 may be formed through the third insulation layer 470 and the fifth and sixth mold layers to expose upper surfaces of portions of the first upper insulating interlayer 530.

In example embodiments, the first and second upper contact holes 572 and 574 may overlap the first and second sacrificial structures 522 and 524, respectively, in the first direction D1. Thus, each of the first and second upper contact holes 572 and 574 may be formed at portions of the fifth and sixth mold layers surrounded by the third sacrificial pillar structures in a plan view.

Processes substantially the same as or similar to those illustrated with respect to FIGS. 1 to 8 may be performed to form third and fourth upper contact holes 576 and 578 exposing upper surfaces of portions of the third insulation layers 470 at different levels in the fifth and sixth mold layers, respectively. In example embodiments, a plurality of third upper contact holes 576 may be spaced apart from each other in the horizontal direction, and a plurality of fourth upper contact holes 578 may be spaced apart from each other in the horizontal direction.

In an example embodiment, a plurality of third upper contact holes 576 may be formed to be spaced apart from each other in the second direction D2 on the third region III of the third substrate 300, and a plurality of fourth upper contact holes 578 may be formed to be spaced apart from each other in the second direction D2 on the third region III of the third substrate 300. The third upper contact holes 576 and the fourth upper contact holes 578 may be spaced apart from each other in the third direction D3, and may be spaced apart from the first and second upper contact holes 572 and 574 in the third direction D3. In example embodiments, each of the third and fourth upper contact holes 576 and 578 may be formed at the portions of the fifth and sixth mold layers surrounded by the third sacrificial pillar structures in a plan view.

In an example embodiment, lower surfaces of the third upper contact holes 576 may be lower than lower surfaces of the fourth upper contact holes 578. Alternatively, the lower surfaces of the third upper contact holes 576 may be higher than the lower surfaces of the fourth upper contact holes 578.

FIG. 36 shows that heights of the lower surfaces of the third upper contact holes 576 decrease as distances from the third upper contact holes 576 to the second region II of the third substrate 300 in the second direction D2 increase, however, the inventive concept is not limited thereto. In some embodiments, the heights of the lower surfaces of the third upper contact holes 576 may increase as the distances from the third upper contact holes 576 to the second region II of the third substrate 300 in the second direction D2 increase.

Likewise, heights of lower surfaces of the fourth upper contact holes 578 may decrease or increase as distances from the fourth upper contact holes 578 to the second region II of the third substrate 300 in the second direction D2 increase.

Further, processes substantially the same as or similar to those illustrated with respect to FIGS. 11 to 16 may be performed to form fifth upper contact holes 580 exposing upper surfaces of portions of the third insulation layers 470 at different levels, respectively, of the fifth and sixth mold layers and being spaced apart from each other in the horizontal direction.

In example embodiments, a plurality of fifth upper contact holes 580 may be spaced apart from each other in the second direction D2 on the second region II of the third substrate 300 to form a fifth upper contact hole column, and a plurality of fifth upper contact hole columns may be spaced apart from each other in the third direction D3.

In example embodiments, the fifth upper contact hole 580 may have a shape of a ring, and a center of the ring may overlap the second sacrificial pillar structure in the first direction D1. The fifth upper contact hole 580 may overlap in the first direction D1 one of the second sacrificial pillar structures among a plurality of second sacrificial pillar structures included in a second sacrificial pillar structure group, which may be located at a center that is surrounded by six vertices of a hexagon.

The process for forming the first and second upper contact holes 572 and 574, the process for forming the third and fourth upper contact holes 576 and 578, and the process for forming the fifth upper contact holes 580 may be performed by the same etching process, or by independent etching processes, respectively.

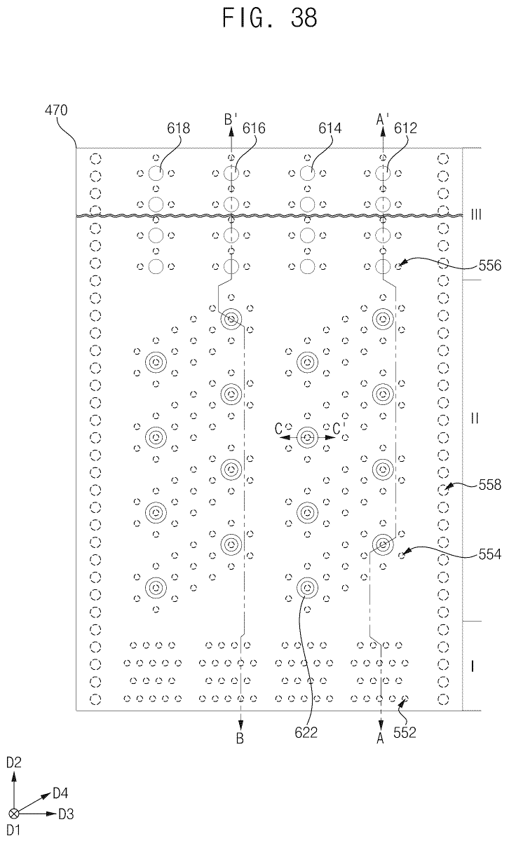

Referring to FIGS. 38 to 41, a second spacer layer may be formed on upper surfaces of portions of the first upper insulating interlayer 530 and portions of the third insulation layers 470 exposed by the first to fifth upper contact holes 572, 574, 576, 578 and 580, inner walls of the first to fifth upper contact holes 572, 574, 576, 578 and 580 and an upper surface of the sixth mold layer, an eighth sacrificial layer may be formed on the second spacer layer to fill the first to fifth upper contact holes 572, 574, 576, 578 and 580, and a planarization process may be performed on the eighth sacrificial layer and the second spacer layer until the upper surface of the sixth mold layer is exposed to form a third sacrificial structure 611, a fourth sacrificial structure, a fifth sacrificial structure 615, a sixth sacrificial structure and a seventh sacrificial structure 621 in the first to fifth upper contact holes 572, 574, 576, 578 and 580, respectively, and second spacers 600 covering lower surfaces and sidewalls of the third, fifth and seventh sacrificial structures 611, 615 and 621 and the fourth and sixth sacrificial structures and contacting the portions of the first upper insulating interlayer 530 and the portions of the third insulation layers 470.

Upper portions of the third sacrificial structure 611, the fourth sacrificial structure, the fifth sacrificial structure 615, the sixth sacrificial structure and the seventh sacrificial structure 612 may be removed to form second to sixth recesses, respectively, and a first sacrificial capping pattern 612, a second sacrificial capping pattern, a third sacrificial capping pattern 616, a fourth sacrificial capping pattern and a fifth sacrificial capping pattern 622 may be formed in the second to sixth recesses, respectively.

Each of the third sacrificial structure 611, the fourth sacrificial structure, the fifth sacrificial structure 615, the sixth sacrificial structure and the seventh sacrificial structure 612 may include, e.g., a carbon-containing material, and each of the first sacrificial capping pattern 612, the second sacrificial capping pattern, the third sacrificial capping pattern 616, the fourth sacrificial capping pattern and the fifth sacrificial capping pattern 622 may include, e.g., polysilicon.

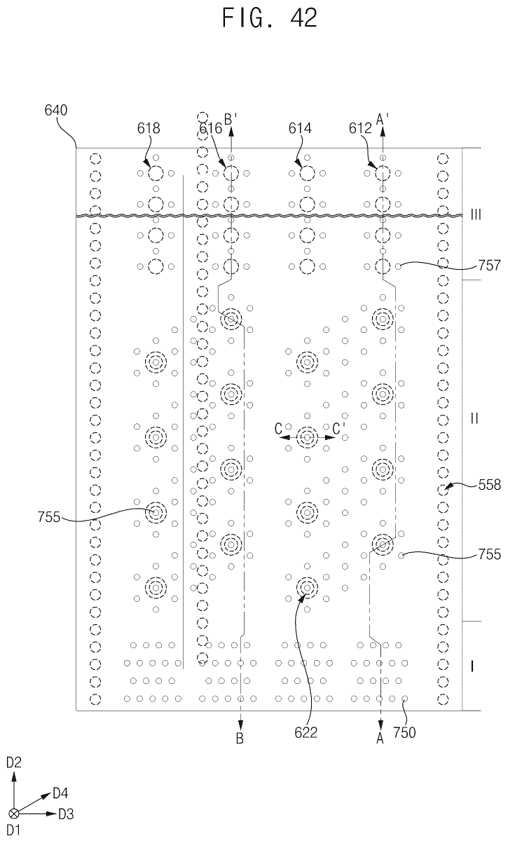

Referring to FIGS. 42 to 46, a second upper insulating interlayer 640 may be formed on the third insulation layer 470, the first, third and fifth sacrificial capping patterns 612, 616 and 622 and the second and fourth sacrificial capping patterns, second to fourth openings may be formed through the second upper insulating interlayer 640 to expose upper surfaces of the first to third sacrificial pillars, respectively, the first to third sacrificial pillars may be removed by, e.g., an ashing process and/or a stripping process through the second to fourth openings to enlarge the second to fourth openings in the first direction D1, and first to third memory channel structures 750, 755 and 757 may be formed in the second to fourth openings, respectively.

In example embodiments, the first memory channel structure 750 may include a first filling pattern 730 extending in the first direction D1, a first channel 720 covering a sidewall and a lower surface of the first filling pattern 730, a first capping pattern 740 on upper surfaces of the first filling pattern 730 and the first channel 720, and a first charge storage structure 710 on a sidewall and a lower surface of the first channel 720 and a sidewall of the first capping pattern 740, and the first charge storage structure 710 may include a first tunnel insulation pattern 700, a first charge storage pattern 690 and a first blocking pattern 680 sequentially stacked on the sidewall and the lower surface of the first channel 720 and the sidewall of the first capping pattern 740.

Additionally, the second memory channel structure 755 may include a second filling pattern 735 extending in the first direction D1, a second channel 725 covering a sidewall and a lower surface of the second filling pattern 735, a second capping pattern 745 on upper surfaces of the second filling pattern 735 and the second channel 725, and a second charge storage structure 715 on a sidewall and a lower surface of the second channel 725 and a sidewall of the second capping pattern 745, and the second charge storage structure 715 may include a second tunnel insulation pattern 705, a second charge storage pattern 695 and a second blocking pattern 685 sequentially stacked on the sidewall and the lower surface of the second channel 725 and the sidewall of the second capping pattern 745.

Further, the third memory channel structure 757 may include a third filling pattern 737 extending in the first direction D1, a third channel 727 covering a sidewall and a lower surface of the third filling pattern 737, a third capping pattern 747 on upper surfaces of the third filling pattern 737 and the third channel 727, and a third charge storage structure 717 on a sidewall and a lower surface of the third channel 727 and a sidewall of the third capping pattern 747, and the third charge storage structure 717 may include a third tunnel insulation pattern 707, a third charge storage pattern 697 and a third blocking pattern 687 sequentially stacked on the sidewall and the lower surface of the third channel 727 and the sidewall of the third capping pattern 747.

The second and third memory channel structures 755 and 757 on the second and third regions II and III, respectively, of the third substrate 300 may not serve as an actual memory or channel, but may be dummy memory channel structure. The second and third memory channel structures 755 and 757 may support the third to sixth mold layers, and thus may also be referred to as first and second dummy memory channel structures 755 and 757, respectively, or first and second support structures 755 and 757, respectively.

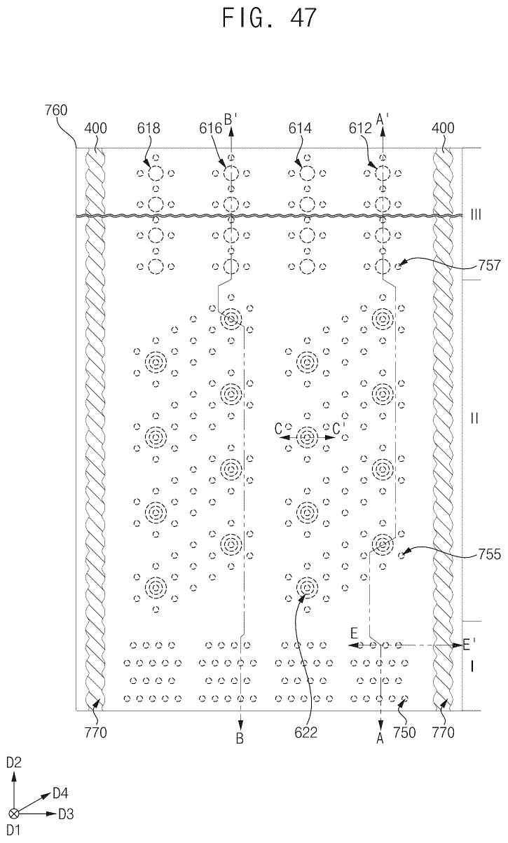

Referring to FIGS. 47 and 48, a third upper insulating interlayer 760 may be formed on the second upper insulating interlayer 640 and the first to third memory channel structures 750, 755 and 757, fifth openings may be formed through the third upper insulating interlayer 760 to expose the fourth sacrificial pillar structures disposed in the second direction D2, the fourth sacrificial pillar structures exposed by the fifth openings may be removed through, e.g., an ashing process and/or a stripping process to form sixth openings disposed in the second direction D2, portions of the third to sixth mold layers, the support layer 460, the support pattern 465, the sacrificial layer structure 450 and the CSP 400 adjacent to the sixth openings may be removed by, e.g., a wet etching process to enlarge horizontal widths of the sixth openings to form a seventh opening 770 extending in the second direction D2.

In example embodiments, the seventh opening 770 may extend through the support pattern 465 to expose the upper surface of the CSP 400 on the second and third regions II and III of the third substrate 300, and may extend through the support layer 460 and the sacrificial layer structure 450 to expose the upper surface of the CSP 400 on the first region I of the third substrate 300.

In example embodiments, the seventh opening 770 may extend in the second direction D2 on the first to third regions I, II and III of the third substrate 300 to opposite end portions in the second direction D2 of the third to sixth mold layers, and a plurality of seventh openings 770 may be spaced apart from each other in the third direction D3. Thus, the third to sixth mold layers may be divided into third to sixth molds, respectively, by the seventh opening 770 on the first to third regions I, II and III of the third substrate 300, and the third insulation layers 470 and the sixth sacrificial layers 480 in each of the third to sixth mold layers may be divided into third insulation patterns 475 and sixth sacrificial patterns 485, respectively, each of which may extend in the second direction D2.

When the third to sixth mold layers are divided into the third to sixth molds extending in the second direction D2 by the etching process, the third to sixth molds may not fall down by the first and second support structures 755 and 757 and the first memory channel structure 750. That is, the first memory channel structures 750, the first support structures 755 and the second support structures 757 may be regularly arranged on the first to third regions I, II and III of the third substrate 300, so that the third to sixth molds may be effectively supported by the first memory channel structures 750, and so that the first support structures 755 and the second support structures 757 do not to fall down.

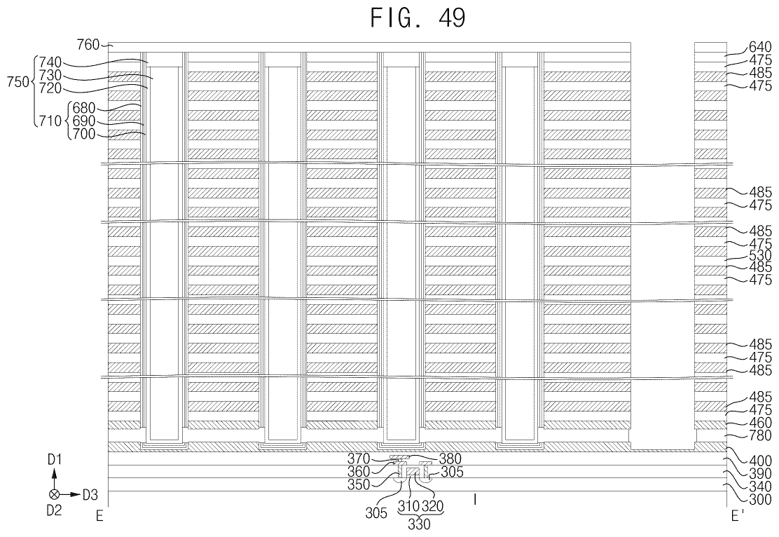

Referring to FIG. 49, a wet etching process may be performed through the seventh opening 770, and thus the sacrificial layer structure 450 may be removed to form a first gap between the CSP 400 and the support layer 460 on the first region I of the third substrate 300.

The wet etching process may be performed using an etching solution, e.g., HF and/or H₃PO₄. In example embodiments, the seventh opening 770 may extend through the support pattern 465 to expose the upper surface of the CSP 400 on the second and third regions II and III of the third substrate 300, instead of extending through the support layer 460 to expose the upper surface of the CSP 400, and thus, when the wet etching process is performed, the sacrificial layer structure 450 may not be removed by the support pattern 465.

As the first gap is formed, a portion of a sidewall of the first charge storage structure 710 may be exposed, and the portion of the sidewall of the first charge storage structure 710 may also be removed by the wet etching process to expose a portion of an outer sidewall of the first channel 720. Thus, the first charge storage structure 710 may be divided into an upper portion extending through the third to sixth mold layers to cover most portion of the outer sidewall of the first channel 720 and a lower portion covering a lower surface of the first channel 720 on the CSP 400.

A channel connection layer may be formed on a sidewall of the seventh opening 770 and in the first gap, and for example, an etch back process may be performed to remove a portion of the channel connection layer in the seventh opening 770 to form a channel connection pattern 780 in the first gap.

As the channel connection pattern 780 is formed, the first channels 720 between neighboring ones of the seventh openings 770 in the third direction D3 on the first region I of the third substrate 300 may be electrically connected to each other.

An air gap may be formed in the channel connection pattern 780.

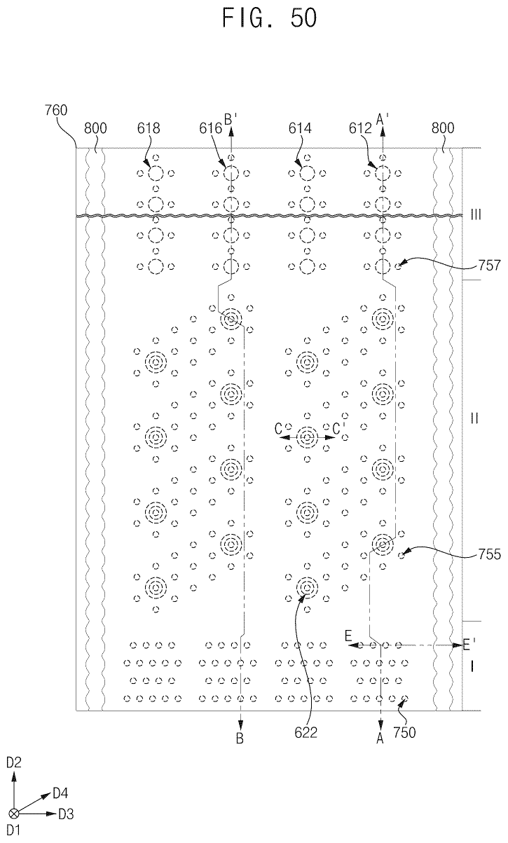

Referring to FIGS. 50 to 54, the sixth sacrificial patterns 485 exposed by the seventh opening 770 may be removed to form a second gap between neighboring ones of the third insulation patterns 475 in the first direction D1, and a portion of an outer sidewall of the first charge storage structure 710 included in the first memory channel structure 750, a portion of a sidewall of each of the first and second support structures 755 and 757, and a portion of a sidewall of the second spacer 600 may be exposed by the second gap.

In example embodiments, the sixth sacrificial patterns 485 may be removed by a wet etching process using an etching solution including, e.g., H₃PO₄ or H₂SO₄.

The wet etching process may be performed through the seventh opening 770, and a portion of the sixth sacrificial pattern 485 between neighboring ones of the seventh opening 770 may be entirely removed by the etching solution that may inflow from the seventh opening 770 in both opposite directions on the first to third regions I, II and III of the third substrate 300.

A fourth blocking layer may be formed on the portion of the outer sidewall of the first charge storage structure 710, the portion of the sidewall of each of the first and second support structures 755 and 757, the sidewall of the second spacer 600, an inner wall of each of the second gaps, surfaces of the third insulation patterns 475 and the first upper insulating interlayer 530, a sidewall of the second upper insulating interlayer 640, and a sidewall and an upper surface of the third upper insulating interlayer 760, and a gate electrode layer may be formed on the second blocking layer.

The gate electrode layer may be partially removed to form first to third gate electrodes 792, 794 and 796 in each of the second gaps. In example embodiments, the gate electrode layer may be partially removed by a wet etching process.

In example embodiments, each of the first to third gate electrodes 792, 794 and 796 may extend in the second direction D2. Each of the first to third gate electrodes 792, 794 and 796 may be formed at a single level or a plurality of levels, and the first to third gate electrodes 792, 794 and 796 may form a gate electrode structure. In example embodiments, a plurality of gate electrode structures may be spaced apart from each other in the third direction D3 by the seventh openings 770.

A first division layer may be formed on the fourth blocking layer to fill the seventh opening 770, and a planarization process may be performed on the first division layer and the fourth blocking layer until an upper surface of the third upper insulating interlayer 760 is exposed.

Thus, the fourth blocking layer may be transformed into a fourth blocking pattern 785, and a first division pattern 800 may be formed in the seventh opening 770.

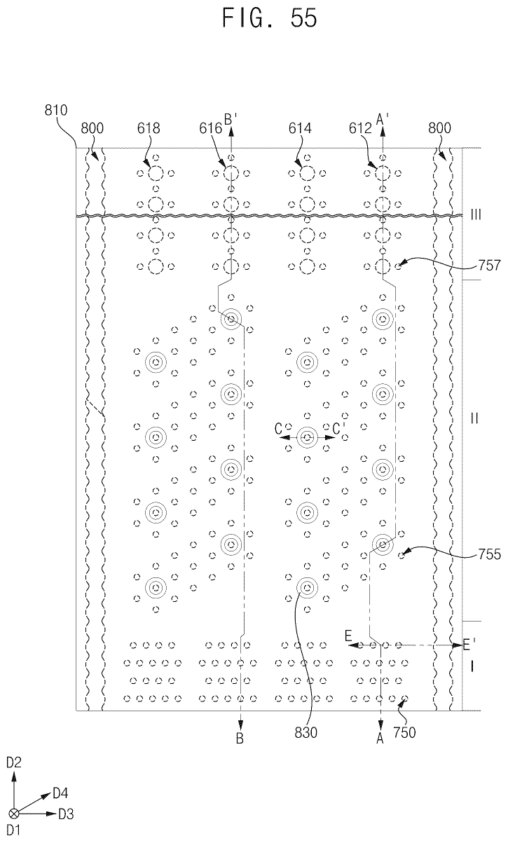

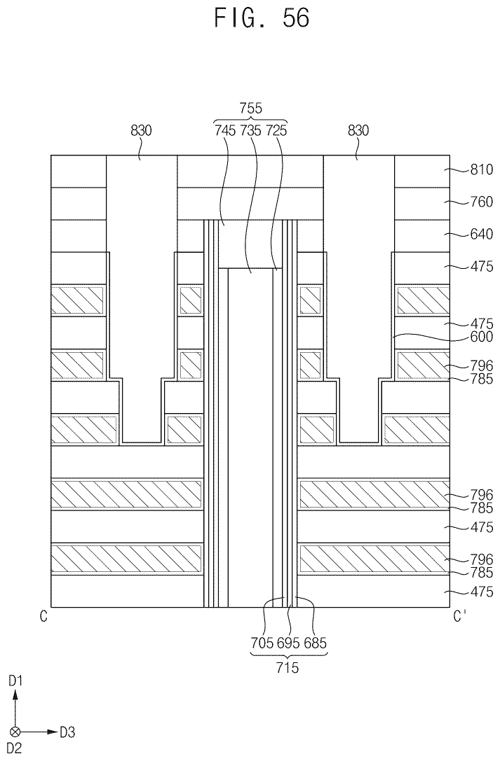

Referring to FIGS. 55 and 56, a fourth upper insulating interlayer 810 may be formed on the third upper insulating interlayer 760, the first division pattern 800 and the fourth blocking pattern 785, an eighth opening may be formed through the second to fourth upper insulating interlayers 640, 760 and 810 to expose an upper surface of the fifth sacrificial capping pattern 622, the fifth sacrificial capping pattern 622 exposed by the eighth opening and the seventh sacrificial structure 621 thereunder may be removed to enlarge the eighth opening in the first direction D1, and an eighth sacrificial structure 830 may be formed in the eighth opening.

In example embodiments, the fifth capping pattern 622 may be removed by, e.g., a dry etching process, and the seventh sacrificial structure 621 may be removed by, e.g., an ashing process and/or a stripping process.

The eighth sacrificial structure 830 may include, e.g., polysilicon.

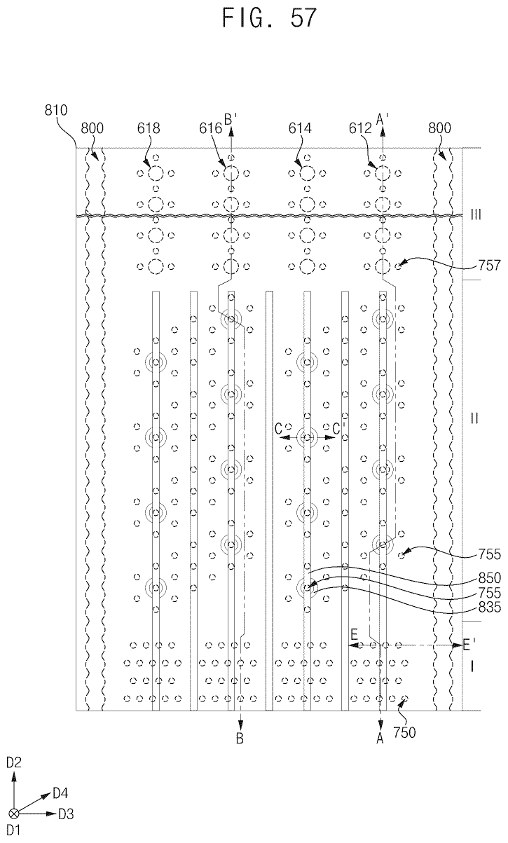

Referring to FIGS. 57 to 61, the second to fourth upper insulating interlayers 640, 760 and 810, the eighth sacrificial structure 830, an upper portion of the first support structure 755, an upper portion of the first memory channel structure 750, the third insulation patterns 475, the third gate electrodes 796 and the fourth blocking pattern 785 on the first and second regions I and II of the third substrate 300 may be partially removed by an etching process to form a ninth opening extending in the second direction D2, and a second division pattern 850 may be formed in the ninth opening.

In example embodiments, a plurality of second division patterns 850, e.g., seven second division patterns 850 may be formed between ones of the first division patterns 800 neighboring in the third direction D3, and may extend through the third gate electrodes 796 and an upper portion of the third insulation pattern 475 directly under a lowermost one of the third gate electrodes 796. Thus, the third gate electrode 796 at each level may be divided into a plurality of parts, e.g., eight parts between the first division patterns 800.

The second division pattern 850 may divide the eighth sacrificial structure 830 having a shape of a ring into two ninth sacrificial structures 835.

Upper portions of some of the first memory channel structures 750 on the first region I of the third substrate 300 may be partially removed by the etching process.

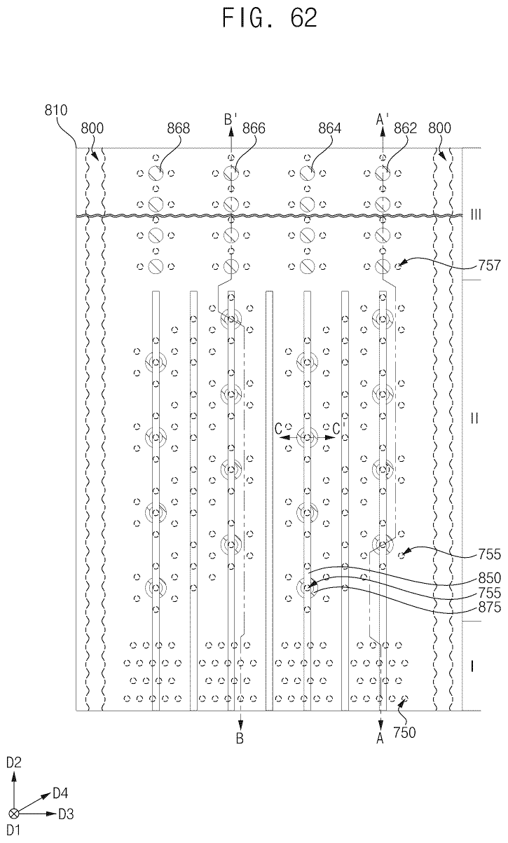

Referring to FIGS. 62 to 65, a sacrificial upper insulating interlayer including substantially the same material as the third insulation pattern 475 may be formed on the fourth upper insulating interlayer 810, the second division pattern 850 and the ninth sacrificial structure 835, tenth to thirteenth openings extending through the sacrificial upper insulating interlayer and the second to fourth insulating interlayers 640, 760 and 810 to expose upper surfaces of the first sacrificial capping pattern 612, the second sacrificial capping pattern, the third sacrificial capping pattern 616 and the fourth sacrificing pattern, respectively and a fourteenth opening extending through the sacrificial upper insulating interlayer to expose an upper surface of the ninth sacrificial structure 835 may be formed, and the first sacrificial capping pattern 612, the second capping pattern, the third capping pattern 616 and the fourth capping pattern exposed by the tenth to thirteenth openings and the ninth sacrificial structure 835 exposed by the fourteenth opening may be removed by an etching process to enlarge the tenth to fourteenth openings in the first direction D1.

The third sacrificial structure 611, the fourth sacrificial structure, the fifth sacrificial structure 615 and the sixth sacrificial structure under the tenth to thirteenth openings, respectively, may be removed by, e.g., an ashing process and/or a stripping process to enlarge the tenth to thirteenth openings in the first direction D1, and portions of the second spacer 600 exposed by the tenth to fourteenth openings may be removed by an etching process to expose a portion of the first upper insulating interlayer 530 and a portion of the third insulation pattern 475.

Processes substantially the same as or similar to those illustrated with respect to FIGS. 9 to 10 and processes substantially the same as or similar to those illustrated with respect to FIGS. 17 and 18 may be performed so that the portion of the first upper insulating interlayer 530 exposed by the tenth and eleventh openings may be removed to expose the first and second sacrificial structures 522 and 524 and that the portions of the third insulation patterns 475 exposed by the twelfth to fourteenth openings may be removed to expose a portion of the fourth blocking pattern 785 and the sacrificial upper insulating interlayer may also be removed.

The first and second sacrificial structures 522 and 524 exposed by the tenth and eleventh openings may be removed by, e.g., an ashing process and/or a stripping process to enlarge the tenth and eleventh openings in the first direction D1, portions of the first spacer 510 exposed by the tenth and eleventh openings may be removed to expose a portion of the fourth blocking pattern 785, and the portions of the fourth blocking pattern 785 exposed by the tenth to fourteenth openings may be removed to expose upper surfaces of the first to third gate electrodes 792, 794 and 796.

First to fifth upper contact plugs 862, 864, 866, 868 and 875 contacting upper surfaces of corresponding ones, respectively, of the first to third gate electrodes 792, 794 and 796 may be formed in the tenth to fourteenth openings.

Referring to FIGS. 19 to 25 again, a fifth upper insulating interlayer 880 may be formed on the fourth upper insulating interlayer 810, the first to fifth upper contact plugs 862, 864, 866, 868 and 875 and the second division pattern 850, and a first upper via 890 extending through the fifth upper insulating interlayer 880 to contact an upper surface of each of the first to fourth upper contact plugs 862, 864, 866 and, 868, a second upper via 895 extending through the fifth upper insulating interlayer 880 to contact an upper surface of the fifth upper contact plug 875, and a third upper via 897 extending through the third to fifth upper insulating interlayers 760, 810 and 880 to contact an upper surface of the first capping pattern 740 included in the first memory channel structure 750 may be formed. The third upper via 897 may also extend through a portion of the second division pattern 850.

A sixth upper insulating interlayer 900 may be formed on the fifth upper insulating interlayer 880 and the first to third upper vias 890, 895 and 897, and first to third upper wirings 910, 915 and 917 extending through the sixth upper insulating interlayer 900 to contact upper surfaces, respectively, of the first to third upper vias 890, 895 and 897 may be formed to complete the fabrication of the semiconductor device.

As illustrated above, processes substantially the same as or similar to those illustrated with respect to FIGS. 1 to 10 and processes substantially the same as or similar to those illustrated with respect to FIGS. 11 to 18 may be performed to form contact holes extending partially through the gate electrode structure to expose an upper surface of a corresponding one of the first to third gate electrodes 792, 794 and 796, the first spacer 510 or the second spacer 600 may be formed on a sidewall of each of the contact holes, and the first to fifth upper contact plugs 862, 864, 866, 868 and 875 may be formed in corresponding ones of the contact holes, so that the first to fifth upper contact plugs 862, 864, 866, 868 and 875 may be formed to be electrically connected to corresponding ones, respectively, of the first to third gate electrodes 792, 794 and 796.

Unlike the first and second gate electrodes 792 and 794, the third gate electrode 796 at a single level may be divided into a plurality of parts by the second division patterns 850. Each of the second division patterns 850 may be formed to divide the eighth sacrificial structure 830 having a ring shape into two parts, and each of the divided eighth sacrificial structures 830 may be replaced by the fifth upper contact plug 875, so that two fifth upper contact plugs 875 may be formed in a relatively small area to increase the integration degree of the semiconductor device.

Additionally, the first support structures 755 may be formed in a regular pattern, e.g., a honeycomb pattern on the second region II of the third substrate 300 in which the fifth upper contact plugs 875 are formed, and thus, during the fabrication of the semiconductor device, the third to sixth molds may be efficiently prevented from collapsing.

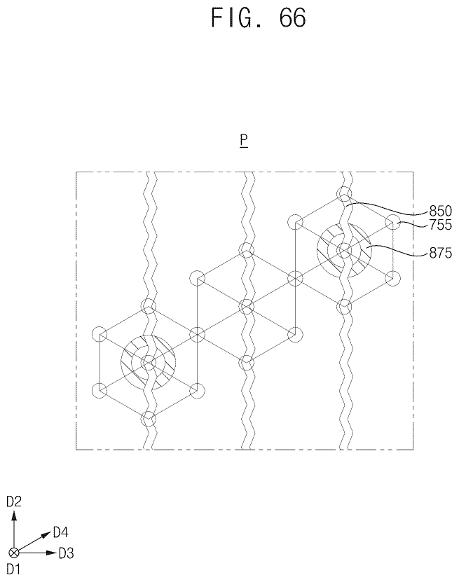

FIGS. 66 to 68 are plan views illustrating layouts of the fifth upper contact plugs, the first support structures and the second division pattern of semiconductor devices in accordance with example embodiments, which may correspond to FIG. 21.

Referring to FIG. 66, the second division pattern 850 may extend in the second direction D2, and may not have a shape of a straight line extending in the second direction D2, but may have, e.g., a wavy shape extending in the second direction D2.

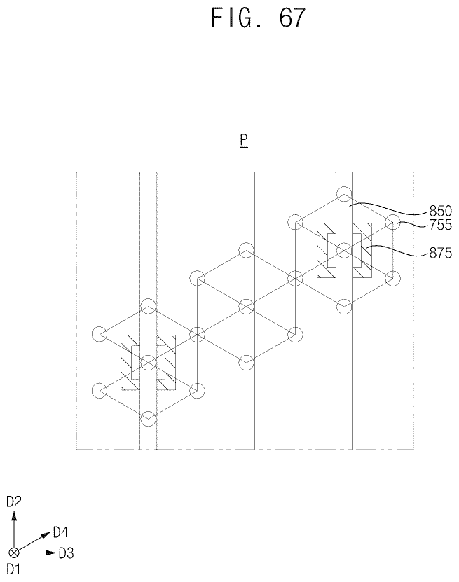

Referring to FIG. 67, the fifth upper contact plug 875 may not have a shape of, e.g., a circular ring or a donut, but may have a portion of a rectangular ring, in a plan view.

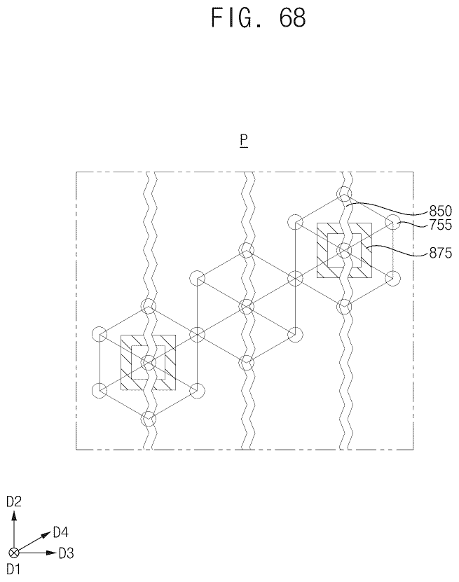

Referring to FIG. 68, the fifth upper contact plug 875 may have a shape of a portion of a rectangular ring, and the second division pattern 850 may have a wavy shape extending in the second direction D2.

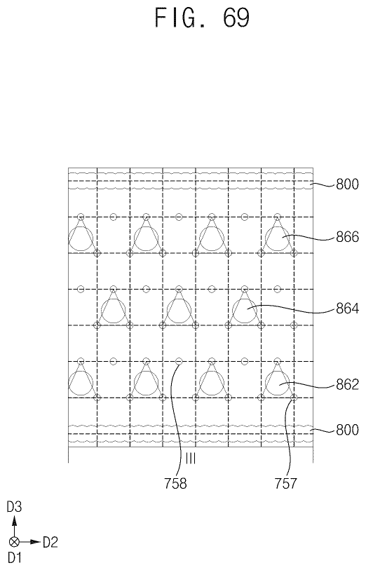

FIG. 69 is a plan view illustrating layouts of the first to third upper contact plugs and the second support structures of a semiconductor device in accordance with example embodiments.

Referring to FIG. 69, the first to third upper contact plugs 862, 864 and 866 may be formed on the third region III of the third substrate 300, and the fourth upper contact plug 868 may not be formed on the third region III of the third substrate 300.

A plurality of first upper contact plugs 862 may be spaced apart from each other in the second direction D2, a plurality of second upper contact plugs 864 may be spaced apart from each other in the second direction D2, a plurality of third upper contact plugs 868 may be spaced apart from each other in the second direction D2, and the first to third upper contact plugs 862, 864 and 868 may be spaced apart from each other in the third direction D3. In example embodiments, the first and third upper contact plugs 862 and 866 may be aligned with each other in the third direction D3, and the second upper contact plugs 864 may not overlap the first and third upper contact plugs 862 and 866 in the third direction D3.

In example embodiments, the second support structures 757 may be arranged at vertices of a triangle surrounding each of the first to third upper contact plugs 862, 864 and 868 in a plan view.

Third support structures 758 may be disposed on the third region III of the third substrate 300. In example embodiments, each of the third support structures 758 may be disposed between ones of the second support structures 757 that are disposed at, e.g., even-numbered columns in the third direction D3 in each memory block, and the second support structures 757 and the third support structures 758 may be alternately and repeatedly arranged in the second direction D2 in a straight line.

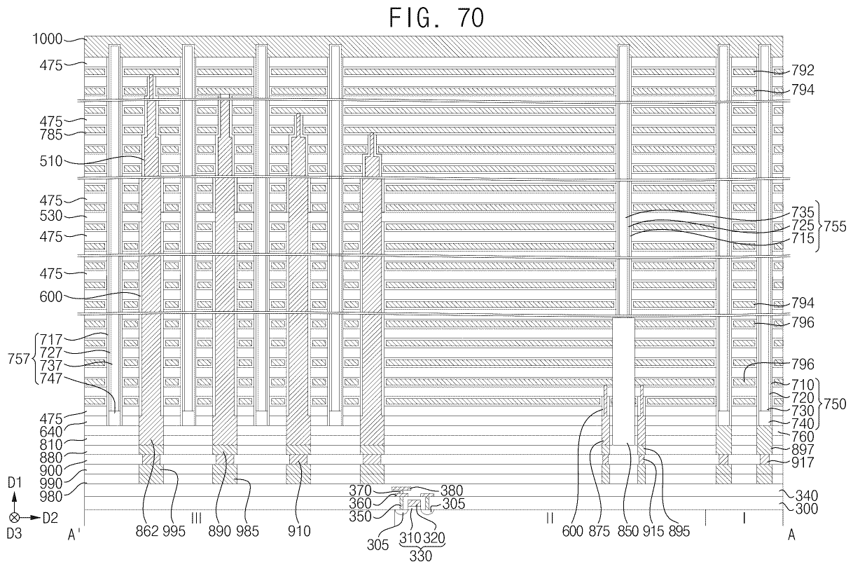

FIG. 70 is a cross-sectional view illustrating a semiconductor device in accordance with example embodiments, which may correspond to FIG. 22.

This semiconductor device may be substantially the same as or similar to that of FIGS. 19 to 25, except that the upper structure is flipped upside down, bonding structures are further disposed, and the channel connection pattern, the support layer and the support pattern are not formed.

Upper and lower portions of structures of the semiconductor device shown in FIGS. 19 to 25 may be referred to as lower and upper portions, respectively, of the structures of the semiconductor device shown in FIG. 69.

Referring to FIG. 70, in example embodiments, first and second bonding layers 980 and 990 may be stacked on the second lower insulating interlayer 390 and the second lower wiring 380.

Additionally, a first bonding pattern 985 may extend through the first bonding layer 980 to contact an upper surface of each of the second lower wirings 380, and a second bonding pattern 995 may extend through the second bonding layer 990 to contact an upper surface of the first bonding pattern 985.

Each of the first and second bonding layers 980 and 990 may include an oxide, e.g., silicon oxide, and each of the first and second bonding patterns 985 and 995 may include a metal, e.g., copper.

An upper portion of each of the first upper contact plugs 862 and the first to third memory channel structures 750, 755 and 757 may extend through a lower portion of a fourth substrate 1000, and upper surfaces and upper sidewalls of the first to third channels 720, 725 and 727 included in the first to third memory channel structures 750, 755 and 757, respectively, may not be covered by the first to third charge storage structures 710, 715 and 717, respectively, but may contact the fourth substrate 1000. The fourth substrate 1000 may include a semiconductor material, e.g., silicon, germanium, silicon-germanium, etc., and n-type impurities or p-type impurities may be doped in the fourth substrate 1000.

While example embodiments have been particularly shown and described, it will be understood by one of ordinary skill in the art that variations in form and detail may be made therein without departing from the spirit and scope of the claims.

What is claimed is:

1. A semiconductor device comprising:
a gate electrode structure on a substrate, the gate electrode structure including gate electrodes stacked and spaced apart from each other in a first direction substantially perpendicular to an upper surface of the substrate facing the gate electrode structure, and each of the gate electrodes extending in a second direction substantially parallel to the upper surface of the substrate;
a memory channel structure extending through the gate electrode structure; and
a first contact plug extending into the gate electrode structure to contact an upper surface of a first gate electrode among the gate electrodes, the first contact plug extending through but being electrically insulated from a second gate electrode that is adjacent to the first gate electrode, and the first contact plug having a shape of a portion of a circular ring, wherein the upper surface of the first gate electrode faces away from the upper surface of the substrate.

2. The semiconductor device according to claim 1, wherein a width of the first contact plug in a horizontal direction parallel to the upper surface of the substrate decreases in the first direction from a top toward a bottom thereof in a stepwise manner.

3. The semiconductor device according to claim 1, further comprising a spacer covering at least a portion of the first contact plug and including an insulating material.

4. The semiconductor device according to claim 3, further comprising a blocking pattern on lower and upper surfaces and a sidewall of the second gate electrode facing the first contact plug in the horizontal direction,
wherein the lower surface of the second gate electrode faces the substrate and is on an opposite side of the second gate electrode from the upper surface of the second gate electrode, and
wherein the spacer contacts the blocking pattern.

5. The semiconductor device according to claim 1, further comprising a division pattern extending through the first and second gate electrodes in the second direction, the division pattern contacting a portion of a sidewall of the first contact plug in a third direction substantially parallel to the upper surface of the substrate and crossing the second direction.

6. The semiconductor device according to claim 5, wherein the division pattern contacts sidewalls in the third direction of opposite end portions of the first contact plug, and the division pattern is spaced apart in the third direction from a sidewall of a central portion in the second direction of the first contact plug, and
wherein the opposite end portions of the first contact plug are spaced apart in the second direction.

7. The semiconductor device according to claim 5, wherein the division pattern has a wavy shape extending in the second direction.

8. The semiconductor device according to claim 5, wherein the first contact plug is one of a pair of first contact plugs that are disposed at opposite sides of the division.

9. The semiconductor device according to claim 8, wherein the pair of first contact plugs are symmetrical in reference to the division pattern.

10. The semiconductor device according to claim 8, further comprising a plurality of first support structures surrounding the pair of first contact plugs in a plane substantially parallel to the upper surface of the substrate, each of the plurality of first support structures extending through the gate electrode structure.

11. The semiconductor device according to claim 10, further comprising a second support structure surrounded by the pair of first contact plugs in the plane substantially parallel to the upper surface of the substrate.

12. The semiconductor device according to claim 11, wherein the division pattern contacts an upper surface of the second support structure.

13. The semiconductor device according to claim 11, wherein the plurality of first support structures are arranged at vertices of a regular hexagon centered around the second support structure.

14. The semiconductor device according to claim 1, further comprising a second contact plug having a pillar shape extending into the gate electrode structure and extending in the first direction,
wherein the second contact plug contacts an upper surface of a third gate electrode among the gate electrodes, extends through but is electrically insulated from a fourth gate electrode among the gate electrodes that is disposed adjacent to the third gate electrode,
wherein a lower surface of the second contact plug is lower than a lower surface of the first contact plug, and
wherein upper surfaces of gate electrodes face away from the upper surface of the substrate and lower surfaces of gate electrodes face towards the upper surface of the substrate.

15. A semiconductor device comprising:
a gate electrode structure on a substrate, the gate electrode structure including gate electrodes stacked and spaced apart from each other in a first direction substantially perpendicular to an upper surface of the substrate facing the gate electrode structure, and the gate electrodes extending in a second direction substantially parallel to the upper surface of the substrate;
a memory channel structure extending through the gate electrode structure; and
a pair of contact plugs extending into the gate electrode structure to contact an upper surface of a first gate electrode among the gate electrodes, each of the pair of contact plugs extending through but being electrically insulated from a second gate electrode that is disposed adjacent to the first gate electrode, the pair of contact plugs being spaced apart from each other in a third direction substantially parallel to the upper surface of the substrate and crossing the second direction, and the pair of contact plugs being symmetrical about a straight line extending in the second direction; and
a plurality of first support structures extending through the gate electrode structure and surrounding the pair of contact plugs in a plane substantially parallel to the upper surface of the substrate.

16. The semiconductor device according to claim 15, further comprising a division pattern extending through the first and second gate electrodes in the second direction, the division pattern contacting a portion of a sidewall in the third direction of each of the pair of contact plugs,
wherein the pair of contact plugs are symmetrical in reference to the division pattern.

17. The semiconductor device according to claim 15, further comprising a second support structure surrounded by the pair of first contact plugs in the plane substantially parallel to the upper surface of the substrate,
wherein the plurality of first support structures are arranged at vertices of a regular hexagon centered around the second support structure.

18. The semiconductor device according to claim 15, wherein each of the pair of contact plugs has a shape of a portion of a circular ring or a rectangular ring.

19. A semiconductor device comprising:
a substrate including first, second and third regions;
a gate electrode structure on the first to third regions of the substrate, the gate electrode structure including gate electrodes stacked and spaced apart from each other in a first direction substantially perpendicular to an upper surface of the substrate facing the gate electrode structure, and each of the gate electrodes extending in a second direction substantially parallel to the upper surface of the substrate;
memory channel structures extending through the gate electrode structure on the first region of the substrate, the memory channel structures being spaced apart from each other in a horizontal direction parallel to the upper surface of the substrate;
a division pattern extending in the second direction on the first and second regions of the substrate, the division pattern extending through a first gate electrode and a second gate electrode adjacent to the first gate electrode among the gate electrodes included in the gate electrode structure;
first contact plugs contacting an upper surface of the first gate electrode and extending through but being electrically insulated from the second gate electrode on the second region of the substrate, the first contact plugs being disposed at opposite sides of the division pattern;
first support structures extending through the gate electrode structure on the second region of the substrate and surrounding the first contact plugs in a plane substantially parallel to the upper surface of the substrate;
a second support structure extending through the gate electrode structure on the second region of the substrate, the second support structure being surrounded by the first contact plugs in the plane substantially parallel to the upper surface of the substrate;
third support structures extending through the gate electrode structure on the third region of the substrate; and
a second contact plug contacting an upper surface of a third gate electrode among the gate electrodes included in the gate electrode structure, the second contact plug extending through but being electrically insulated from a fourth gate electrode adjacent to the third gate electrode among the gate electrodes included in the gate electrode structure,
wherein upper surfaces of gate electrodes face away from the upper surface of the substrate.

20. The semiconductor device according to claim 19, wherein a width of each of the first and second contact plugs decreases in the first direction from a top toward a bottom thereof in a stepwise manner.
